(19) United States
(12) Patent Application Publication
(10) Pub. No.: US 2025/0118592 A1
(43) Pub. Date: Apr. 10, 2025

(54) APPARATUSES FOR BACKSIDE WAFER PROCESSING WITH EDGE-ONLY WAFER CONTACT

(71) Applicant: Lam Research Corporation, Fremont, CA (US)

(72) Inventors: Nick Ray Linebarger, Jr., Tualatin, OR (US); Richard M. Blank, San Jose, CA (US); Daniel Boatright, Estacada, OR (US); Fayaz A. Shaikh, Lake Oswego, OR (US); Eric Thomas Dixon, Hillsboro, OR (US); Michael John Janicki, Portland, OR (US); Adriana Vintila, Wilsonville, OR (US); Xin Yin, Beaverton, OR (US); Conor Charles Arcuri, Beaverton, OR (US)

(73) Assignee: Lam Research Corporation, Fremont, CA (US)

(21) Appl. No.: 18/730,257

(22) PCT Filed: Jan. 18, 2023
(86) PCT No.: PCT/US2023/011056

§ 371 Date: Jul. 18, 2024

Related U.S. Application Data
(60) Provisional application No. 63/368,974, filed on Jul. 20, 2022.
(60) Provisional application No. 63/301,961, filed on Jan. 21, 2022.

(51) Int. Cl. H01L 21/687; H01J 37/32; H01L 21/68

(52) U.S. Cl. CPC H01L 21/6875; H01J 37/3244; H01J 37/32642; H01J 37/32715; H01L 21/68; H01J 2237/20214

(57) ABSTRACT

Semiconductor processing tools with wafer back-side processing capabilities are disclosed. Such tools may be configured to only contact wafers being processed through edge contact, as opposed to underside/planar contact. Such tools may also include wafer-centering features that may allow such wafers to be precisely centered with regard to a particular wafer processing station thereof.

### RELATED APPLICATION(S)

An Application Data Sheet is filed concurrently with this specification as part of the present application. Each application that the present application claims benefit of or priority to as identified in the concurrently filed Application Data Sheet is incorporated by reference herein in its entirety and for all purposes.

### BACKGROUND

Semiconductor processing tools typically include one or more pedestals that are used to support semiconductor wafers within a semiconductor processing chamber. Such pedestals feature wafer support surfaces that are designed to have wafers placed thereupon and to support those wafers during semiconductor processing operations within the semiconductor processing chamber. Pedestals may be equipped with any of a variety of ancillary systems, including, for example, vacuum chucks and/or electrostatic chucks (which may provide the wafer support surface of the pedestal), heating and/or cooling systems, electrodes used for radio-frequency energy transmission purposes, purge gas systems for protecting the undersides of wafers from process gases that are intended to only be applied to the upward-facing sides of the wafers, lift-pin mechanisms that may be used to raise wafers off of the wafer support surface (or lower wafers onto the wafer support surface), etc. In such tools, the top surface of the wafer is subjected to wafer processing operations while the bottom surface of the wafer rests on the pedestal. The wafer is typically clamped into place on the pedestal using a vacuum or electrostatic forces in order to maximize thermal coupling between the wafer and the pedestal, maintain wafer flatness during processing, and/or reduce the possibility of processing gases reaching the underside of the wafer. In some such semiconductor processing tools, a showerhead (sometimes referred to as a gas distributor) may be positioned above the pedestal. The showerhead may have a plurality of gas distribution ports distributed across a surface thereof that faces towards the pedestal. Such gas distribution ports are fluidically connected with one or more plenums located within the showerhead. The one or more plenums are, in turn, fluidically connected with one or more processing gas sources that may be controlled so as to selectively flow processing gases across the top surface of a wafer supported by the pedestal.

A relatively new type of semiconductor processing tool, described in U.S. Pat. Nos. 9,881,788 and 10,851,457 operates in a fundamentally different manner from the above-described semiconductor processing tools. In such newer semiconductor processing tools, the pedestal on which the wafer normally rests during semiconductor processing operations is replaced with a shower-pedestal, which is a pedestal-like structure that has a large number of gas distribution ports distributed across its upper surface (much like a showerhead has a number of gas distribution ports distributed across its underside). The gas distribution ports are fluidically connected with one or more plenums located within the shower-pedestal. The one or more plenums are, in turn, fluidically connected with one or more processing gas sources that are controllable so as to allow processing gases to be flowed out of the shower-pedestal via those gas distribution ports. Such semiconductor processing tools may also have one or more carrier ring supports that may be configured to support a carrier ring that may, in turn, support a wafer during processing operations. The one or more carrier ring supports are designed to allow the carrier ring and any wafer supported thereby to be held at an elevated location above the shower-pedestal, such that there is a gap in between the shower-pedestal and the wafer to which processing gas is able to be delivered. Such semiconductor processing tools thus allow the underside of the wafer to be subjected to wafer processing operations instead of the top side of the wafer, a complete reversal from the conventional wafer processing approach.

### SUMMARY

Details of one or more implementations of the subject matter described in this specification are set forth in the accompanying drawings and the description below. Other features, aspects, and advantages will become apparent from the description, the drawings, and the claims.

In some implementations, an apparatus may be provided that includes a shower-pedestal having a plurality of first gas distribution ports distributed across a first surface thereof. The first surface of the shower-pedestal may define a first average midplane. The apparatus may further include a plurality of wafer support structures extending from the shower-pedestal and positioned about a first reference axis that intersects the first surface of the shower-pedestal and is perpendicular to the first average midplane. The plurality of wafer support structures may be further positioned around a region that includes the first surface of the shower-pedestal, each wafer support structure may have a corresponding wafer support surface that is non-parallel with respect to the first average midplane, and each wafer support surface may have a portion that is positioned at least a first distance away from the first average midplane in a direction perpendicular thereto and a second distance from the first reference axis in a direction perpendicular thereto.

In some further implementations, at least a portion of each wafer support surface may form an angle of greater than zero degrees and equal to or less than 15 degrees with respect to the first average midplane.

In some further implementations, each wafer support structure may include a corresponding cantilever beam structure and a corresponding riser structure. For each wafer support structure, the corresponding cantilever beam structure for that wafer support structure may extend radially inward towards the first reference axis from the corresponding riser structure for that wafer support structure, the corresponding cantilever beam structure for that wafer support structure may have a proximal end that is connected with the corresponding riser structure for that wafer support structure, and the corresponding cantilever beam structure for that wafer support structure may have a distal end at which the corresponding wafer support surface for that wafer support structure is located.

In some further implementations, each cantilever beam structure may have a corresponding channel in a side of that cantilever beam structure facing away from the first average midplane, the corresponding channel of each cantilever beam structure may be located between the wafer support surface of that cantilever beam structure and the corresponding riser structure connected with the proximal end of that cantilever beam structure, and the corresponding channel of each cantilever beam structure may extend across that cantilever beam structure in a direction that is transverse to a long axis of the cantilever beam structure.

In some further implementations, each channel may be at least 0.75 mm deep.

In some further implementations, the apparatus may further include a plurality of wafer-centering features, each wafer-centering feature having a corresponding centering surface. At least a portion of the centering surface of each wafer-centering feature may be positioned a third distance from, and face towards, the first reference axis.

In some further implementations, the third distance may be between 150.5 mm and 150 mm.

In some further implementations, each wafer-centering feature may be fixed in space with respect to, and supported by, a corresponding one of the wafer support structures.

In some further implementations, at least a portion of the centering surface of each wafer-centering feature may form an angle of less than 90 degrees with respect to the first reference axis.

In some further implementations, at least a portion of the centering surface of each wafer-centering feature may form an acute angle with respect to the first reference axis that is greater than 0 degrees and less than or equal to 30 degrees.

In some further implementations, the wafer-centering features may be wheels. In some further implementations, the wheels may be made of a ceramic material. In some further implementations, each wheel may be supported by a corresponding one of the wafer support structures relative to the shower-pedestal and may be configured to rotate about an axis that is at a fixed distance relative to the first average midplane.

In some further implementations, the apparatus further includes a showerhead with a plurality of second gas distribution ports distributed across a second surface of the showerhead that faces towards the first surface of the shower-pedestal. In such an implementations, there may be N wheels, the second surface of the showerhead may have N recesses in it, and each recess may be positioned such that a corresponding second reference axis that is perpendicular to the first average midplane and that passes through a center of a corresponding one of the wheels passes through that recess.

In some further implementations, the apparatus may further include a focus ring. The focus ring may have a nominally circular inner edge with a diameter that is smaller than twice the third distance and a nominally circular outer edge that has a diameter that is larger than twice the third distance. The focus ring may also be configured to rest on the wafer support structures and may include N openings proximate the inner edge or N notches along the inner edge that are each positioned such that a portion of a corresponding one of the wheels passes through the opening or notch when the focus ring is supported by the wafer support structures.

In some implementations, the focus ring may have a top surface and a bottom surface and may be associated with a center axis and a reference plane that is perpendicular to the center axis and coincident with the top surface. In such implementations, the bottom surface may have a first circumferential profile at a radial distance X from the center axis that varies such that a normal distance from the reference plane to the bottom surface at the radial distance X periodically varies between at least a first value and a second value. In such implementations, a value twice that of X may be larger than the diameter of the nominally circular inner edge and smaller than the diameter of the nominally circular outer edge.

In some implementations, the focus ring may further include a plurality of protrusions positioned along the bottom surface, each protrusion having a portion lying at the radial distance X from the center axis.

In some implementations, each protrusion may extend along a corresponding axis that is coplanar with a corresponding reference plane that is coplanar with the center axis.

In some implementations, each protrusion may be semi-cylindrical in shape.

In some implementations, the focus ring may have an inner portion and an outer portion, the inner edge may be located on the inner portion, the inner portion may be sized such that it cannot pass through an opening defined by an innermost edge of the outer portion, and the inner portion and the outer portion may not be fixedly connected with one another.

In some further implementations, the apparatus may include one or more wheel vertical lift mechanisms. Each wheel may be supported by a corresponding wheel riser structure, the one or more vertical lift mechanisms, in aggregate, may support the wheel riser structures and may be configured to be movable between at least a first configuration and a second configuration, at least a portion of each wheel may be farther from the first average midplane in a direction parallel to the first reference axis than the wafer support surfaces when the one or more vertical lift mechanisms are in the first configuration, and each wheel may, when the one or more vertical lift mechanisms are in the second configuration, be in between the first average midplane and the location that that wheel was in when the one or more vertical lift mechanisms were in the first configuration.

In some further implementations, the one or more vertical lift mechanisms may be further configured to be movable between at least the first and second configurations and also a third configuration, and the first average midplane may be in between the wafer support surfaces and at least a portion of each wheel when the one or more vertical lift mechanisms are in the third configuration.

In some further implementations, each wheel riser structure may pass through a corresponding notch in an outer edge of the shower-pedestal or through a corresponding hole through the shower-pedestal.

In some further implementations, each wheel riser structure may be located at a different angular position about the first reference axis than the wafer support structures.

In some further implementations, each wheel riser structure may be located at the same angular position about the first reference axis as a corresponding one of the wafer support structures.

In some further implementations, each wafer support structure may have an opening therethrough that is sized such that a portion of a corresponding one of the wheel riser structures passes through the opening when the one or more vertical lift mechanisms is moved between the first configuration to the second configuration.

In some further implementations, the apparatus may further include a chamber and a rotational indexer having a plurality of forks. The rotational indexer may be configured to rotate the plurality of forks about a first rotational axis to at least a first rotational position responsive to one or more inputs, each fork may have a plurality of wafer lift surfaces, and a first fork of the plurality of forks may be positioned such that the wafer lift surfaces thereof are positioned over the shower-pedestal when the plurality of forks are in the first rotational position.

In some further implementations, the first fork may include two arms that, when the plurality of forks are in the first rotational position, lie entirely outside of a circular region centered on the first reference axis and having a diameter of twice the third distance, and each of the arms may have one or more protrusions that, when the plurality of forks are in the first rotational position, extend inward towards the first reference axis such that a portion of each protrusion having one of the wafer lift surfaces lies within the circular region.

In some further implementations, each wafer lift surface may be non-parallel with respect to the first average midplane.

In some further implementations, at least a portion of each wafer lift surface may form an angle of greater than zero degrees and equal to or less than 25 degrees with respect to the first average midplane.

In some further implementations, the forks may each include a first half and a second half, at least one of the wafer lift surfaces of each fork may be provided by the first half of that fork, at least one other of the wafer lift surfaces of each fork may be provided by the second half of that fork, the first halves of the forks may be fixed in space with respect to a first hub, the second halves of the forks may be fixed in space with respect to a second hub, the first hub may be connected with a first rotational drive by a first shaft, the second hub, may be connected with a second rotational drive by a second shaft, and the first rotational drive and the second rotational drive may be configured to be independently actuated for at least a portion of their rotational range of motion.

In some implementations, an apparatus for use with semiconductor wafers of diameter D may be provided. Such an apparatus may include a ring structure having an inner perimeter defining an opening sized smaller than the semiconductor wafers of diameter D and an outer perimeter sized larger than the semiconductor wafers of diameter D. The ring structure may have a top surface and a bottom surface and be associated with a center axis and a reference plane that is perpendicular to the center axis and coincident with the top surface. The bottom surface may have a first circumferential profile at a radial distance X from the center axis that varies such that a normal distance from the reference plane to the bottom surface at the radial distance X varies between at least a first value and a second value. X may be less than 50% of D.

In some implementations, the normal distance from the reference plane to the bottom surface at the radial distance X may vary periodically.

In some such implementations, the normal distance from the reference plane to the bottom surface at the radial distance X may vary periodically with a periodicity of at least three periods about the circumference of the ring structure.

In some implementations, the normal distance from the reference plane to the bottom surface at the radial distance X may vary periodically with a periodicity of three periods about the circumference of the ring structure.

In some implementations, the normal distance from the reference plane to the bottom surface at the radial distance X may vary periodically with a periodicity of four periods about the circumference of the ring structure.

In some such implementations, the normal distance from the reference plane to the bottom surface at the radial distance X may vary periodically with a periodicity of at least four periods and less than or equal to ten periods about the circumference of the ring structure.

In some such implementations, the normal distance from the reference plane to the bottom surface at the radial distance X may vary periodically with a periodicity of more than ten periods and less than or equal to twenty periods about the circumference of the ring structure.

In some such implementations, the normal distance from the reference plane to the bottom surface at the radial distance X may vary periodically with a periodicity of more than twenty periods and less than or equal to thirty periods about the circumference of the ring structure.

In some implementations, there may be N spaced-apart first locations about the ring structure where the normal distance from the reference plane to the bottom surface at the radial distance X is at the first value, there may be N spaced-apart second locations about the ring structure where the normal distance from the reference plane to the bottom surface at the radial distance X is at the second value, each first location may be circumferentially interposed between two of the second locations, each second location may be circumferentially interposed between two of the first locations, and N may be an integer greater than or equal to three.

In some such implementations, N may be three or four. In some other implementations, N may be an integer greater than three and less than or equal to thirty, greater than three and less than or equal to ten, greater than ten and less than or equal to twenty, or greater than twenty and less than or equal to thirty.

In some implementations, the absolute value of the difference between the first value and the second value may be greater than zero microns and less than or equal to 400 microns.

In some implementations, the absolute value of the difference between the first value and the second value may be greater than zero microns and less than or equal to 100 microns, greater than or equal to 50 microns and less than or equal to 150 microns, greater than or equal to 100 microns and less than or equal to 200 microns, greater than or equal to 150 microns and less than or equal to 250 microns, greater than or equal to 200 microns and less than or equal to 300 microns, greater than or equal to 250 microns and less than or equal to 350 microns, or greater than or equal to 300 microns and less than or equal to 400 microns.

In some implementations, the absolute value of the difference between the first value and the second value may be greater by a third value than an expected maximum amount of wafer edge sag in the semiconductor wafers when the semiconductor wafers are supported at a plurality of locations along edges thereof. In some such implementations, the third value may be greater than zero microns and less than or equal to 50 microns. In some other such implementations, the third value may be greater than zero microns and less than or equal to 40 microns. In some other such implementations, the third value may be greater than zero microns and less than or equal to 30 microns. In some other such implementations, the third value may be greater than zero microns and less than or equal to 20 microns.

In some implementations, the top surface may be planar or at least axially symmetric about the center axis. In some other implementations, the top surface may have a second circumferential profile that follows the first circumferential profile.

In some implementations, the bottom surface at the radial distance X from the center axis may be a wavy conical frustum.

In some implementations, the bottom surface at the radial distance X from the center axis may have a radial profile with respect to the center axis that is at an oblique angle with respect to the center axis.

In some implementations, the ring structure may be made of a ceramic material. In some such implementations, the ceramic material may be aluminum oxide.

### BRIEF DESCRIPTION OF THE DRAWINGS

Reference to the following Figures is made in the discussion below; the Figures are not intended to be limiting in scope and are simply provided to facilitate the discussion below.

FIG. 1 depicts an example shower-pedestal and associated structures.

FIG. 2 depicts a similar shower-pedestal to the shower-pedestal shown in FIG. 1.

FIG. 3 depicts a detail view of the portion of FIG. 1 that is enclosed within the dash-dot-dash circle.

FIG. 4 depicts an isometric detail view of the implementation of a wafer-centering feature and wafer support structure shown in FIGS. 1 through 3.

FIG. 4′ shows the same implementation as FIG. 4 but with the wheel retracted into the shower-pedestal.

FIG. 5 shows an example implementation in which wafer-centering features are circumferentially offset with respect to a first reference axis as compared with wafer support structures.

FIG. 5′ shows the same implementation as FIG. 5, but with the wheel riser structures retracted into the shower-pedestal.

FIG. 6 shows example wafer-centering features that are supported by, and fixed in space relative to, wafer support structures.

FIG. 7 depicts an example implementation of a wafer support structure that has a wafer-centering feature that includes a protrusion.

FIG. 8 depicts a view of an example shower-pedestal as well as a showerhead and focus ring.

FIG. 9 depicts the showerhead and the shower-pedestal of FIG. 8 positioned as they might be during actual wafer processing operations.

FIG. 10 depicts an example of a showerhead and a shower-pedestal that includes wafer support structures that are similar to those shown in FIGS. 4 and 4′.

FIG. 11 depicts an isometric view of a shower-pedestal with four wafer support structures.

FIG. 12 depicts an example four-station semiconductor processing tool.

FIG. 13 depicts a perspective view of an example fork with a wafer.

FIGS. 14 through 26 depict an arrangement of four stations similar to those shown in FIG. 12 during various stages of wafer placement and positioning operations.

FIG. 27 depicts a simplified schematic view of a semiconductor processing tool having mechanisms and systems such as are discussed below.

FIGS. 28 through 31 depict representations of a rotational indexer with openable and closable forks.

FIG. 32 depicts an example of a wafer being supported over a shower-pedestal and exhibit wafer edge sag.

FIG. 33 depicts a side view of FIG. 32.

FIG. 34 depicts a top view of an example ring structure, wafer, and shower-pedestal.

FIGS. 35 and 36 depict circumferential profiles of the example ring structure and wafer of FIG. 34.

FIG. 37 depicts a top view of a ring structure and wafer.

FIG. 38 depicts a section view of FIG. 37.

FIG. 39 depicts a detail view of FIG. 38.

FIGS. 40 and 41 depict dimetric views of a ring structure with an axially symmetric top surface.

FIGS. 42 and 43 depict dimetric views of a ring structure with a top surface having a varying circumferential profile.

FIGS. 44 and 45 depict side views of an example shower-pedestal with an example ring structure and wafer.

FIG. 46 depicts an isometric bottom view of an example ring structure having six protrusions located on the bottom surface.

FIG. 47 depicts a detail view of a portion of the ring structure of FIG. 46.

FIG. 48 depicts an isometric sectional view of an example showerhead and shower-pedestal supporting a wafer.

FIGS. 49 through 51 depict detail views of the circled portion of FIG. 48.

FIG. 52 is an isometric view of a focus ring with an inner portion and an outer portion.

FIG. 53 is an isometric view of the focus ring of FIG. 52 with the inner portion lifted clear of the outer portion.

FIG. 54 is a cross-sectional view of the focus ring of FIG. 52.

FIG. 55 is a detail view of the circled portion of FIG. 54.

The above-described Figures are provided to facilitate understanding of the concepts discussed in this disclosure, and are intended to be illustrative of some implementations that fall within the scope of this disclosure, but are not intended to be limiting—implementations consistent with this disclosure and which are not depicted in the Figures are still considered to be within the scope of this disclosure.

### DETAILED DESCRIPTION

Disclosed herein are systems and apparatuses for use in semiconductor processing tools that perform processing operations on the undersides of substrates (also referred to simply as “wafers” herein). As discussed above, U.S. Pat. Nos. 9,881,788 and 10,851,457 describe examples of semiconductor processing tools that are designed to facilitate the performance of wafer processing operations on the undersides of wafers. Such systems use a carrier ring to support such wafers during such operations; the carrier ring is supported above a shower-pedestal and, in turn, supports the wafer over the shower-pedestal such that there is a gap, e.g., at least several millimeters, between the underside of the wafer and the surface of the shower-pedestal immediately therebeneath. The carrier rings in such systems, however, contact the underside of the wafer, e.g., along an annular region extending radially inward from the wafer edge which rests on a corresponding annular region of the carrier ring, or at multiple smaller regions that rest on tabs that extend radially inward from the inner perimeter of the carrier ring. In either case, the surfaces that the wafer rests on make planar contact with the underside of the wafer. It was determined that such wafer support mechanisms resulted, in some cases, in an undesirable “shadowing” effect in which the surfaces of the wafer that were in contact with the carrier ring, or the regions of the wafer in the immediate vicinity did not experience the same amount of processing as did the remainder of the wafer. For example, such regions may experience a lower level of deposition than other regions of the wafer. Such non-uniformities may cause the usable area of the wafer to be reduced, thereby reducing wafer yield.

The present inventors conceived of apparatuses, systems, and methods that allow such wafer backside processing to be performed while supporting the wafer through edge contact, as opposed to through planar contact as is the case with the carrier ring-based system discussed above. By supporting the wafer through edge contact, the shadowing effect on the wafer may be reduced or eliminated, thereby reducing or eliminating the magnitude of non-uniformities that may arise on the underside of the wafer in the vicinity of locations where the wafer is supported. Moreover, such systems allow the wafer to be supported without the use of a carrier ring, which may decrease cost, tooling inventory, and complexity.

Wafers are typically provided with beveled or rounded top and bottom edges to reduce the likelihood of peeling, arcing, edge chipping, or other issues with the wafers during processing. However, the systems disclosed herein may be used with both beveled or rounded edge wafers or non-beveled or non-rounded edge wafers.

The various concepts relating to the use of edge-supported wafers during backside processing of such wafers are discussed below with respect to the various Figures.

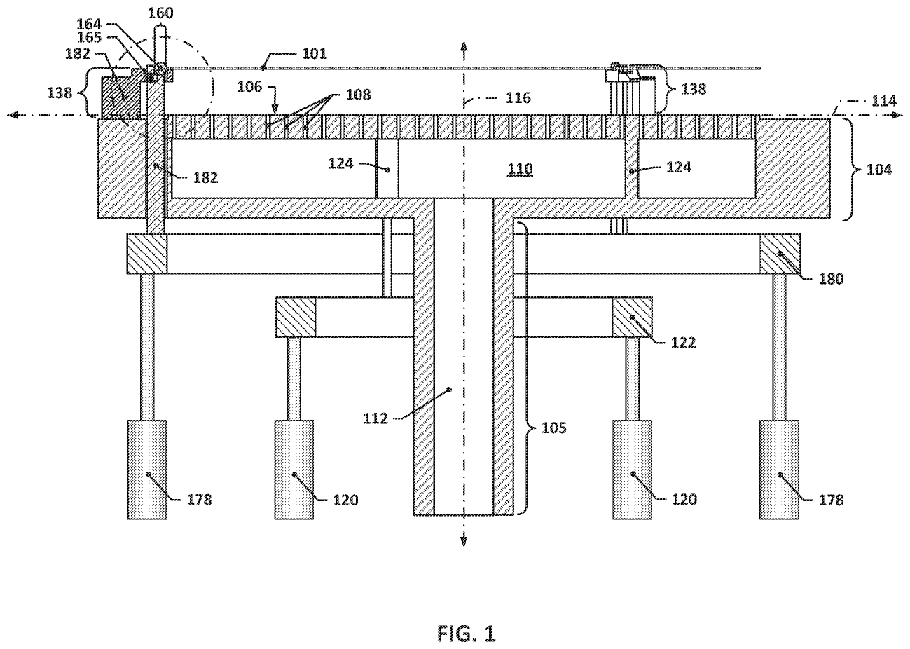

FIG. 1 depicts an example shower-pedestal and associated structures. As can be seen, the shower-pedestal 104 houses a first plenum 110 and a plurality of first gas distribution ports 108 that extend from a first surface 106 to the first plenum 110. The first gas distribution ports 108 may fluidically connect the first plenum 110 with a processing region positioned in between the first surface 106 and, when present, a wafer 101. Gas distribution ports, as the term is used herein, refer to small ports, orifices, holes, or openings in a shower-pedestal or showerhead, depending on the context, through which gases may exit the shower-pedestal or showerhead, as appropriate, after being provided to the shower-pedestal or showerhead via a gas inlet or gas inlets. A large number of gas distribution ports, e.g., dozens, hundreds, or, in some cases, thousands, of gas distribution ports may be distributed across the surface of a shower-pedestal or showerhead that faces towards a wafer during processing operations so as to deliver process gases to the wafer in a desired manner. During semiconductor processing operations, the first plenum 110 may be provided one or more processing gases via first gas inlet 112 that passes through a stem 105 that supports the shower-pedestal 104.

The shower-pedestal 104 may generally include a sidewall that extends around the first plenum 110, a bottom wall (which may extend from the stem 105 to the sidewall, and a top wall (through which the first gas distribution ports 108 extend).

An average midplane of a surface is a plane that intersects with the surface and is positioned such that the maximum distances between the average midplane and the points on that surface that are furthest from the average midplane are at a minimum. For a first surface 106 that is planar, e.g., such as the one shown in FIG. 1, the first average midplane 114 is a plane that is co-planar with the first surface 106.

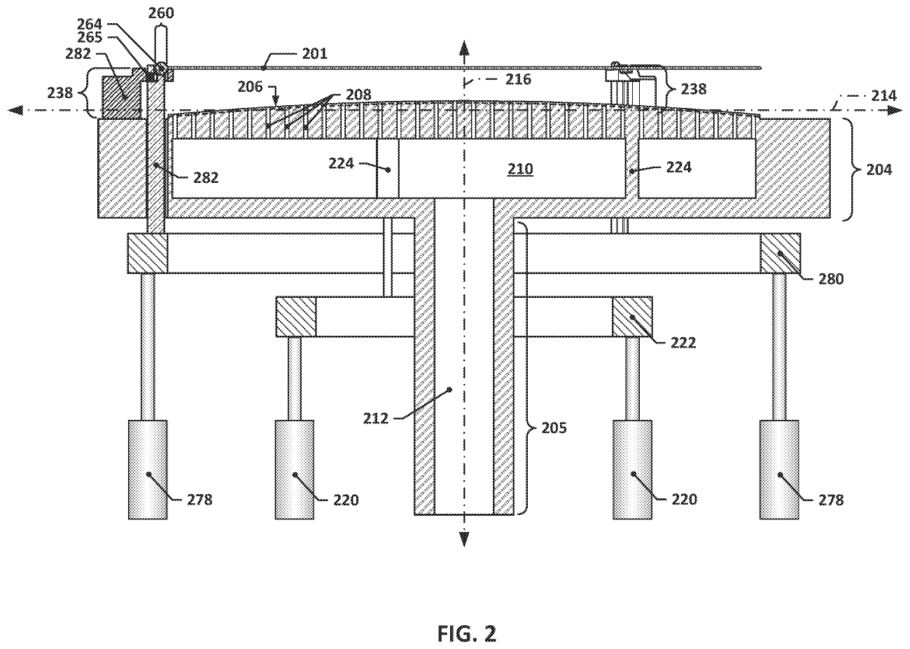

FIG. 2 depicts a similar shower-pedestal 204 to the shower-pedestal 104 shown in FIG. 1. Structures in FIG. 2 that are similar to corresponding structures in FIG. 1 are indicated with callouts having the same last two digits and the discussion of such elements with respect to FIG. 1 is equally applicable to the corresponding elements in FIG. 2. The only difference between the shower-pedestal 104 and associated components in FIG. 1 and the corresponding shower-pedestal 204 and associated components in FIG. 2 is that the shower-pedestal 204 has a first surface 206 that is non-planar. In this example, the first surface 206 bulges upward toward the wafer 201 in the middle, giving the first surface 206 a domed appearance. As can be seen, the first average midplane 214 is no longer co-planar with the first surface 206 (it cannot be, due to the curvature of the first surface 206). However, the volumes trapped between the first average midplane 214 and the first surface 206 on either side of the first average midplane 214 are equal, and the maximum distances between the first average midplane 214 and the first surface 206 on either side of the first average midplane 214 are at a minimum. Thus, the first average midplane 214 may generally act as a stand-in for a planar first surface 106 in shower-pedestals 104 having contoured first surfaces 106.

The first reference axis 116 may generally represent the center axis of the shower-pedestal or, perhaps more accurately, be positioned at a location that is intended to cause the first reference axis 116 to pass through the center of the wafer 101 when the wafer 101 is present and properly positioned.

The shower-pedestal 104 may support a plurality of wafer support structures 138 that may be positioned at locations around the first surface 106; in this example, there are three wafer support structures 138, although other implementations may have different numbers of wafer support structures 138. Wafer support structures, as used herein, refer to structures that are configured to have a wafer placed thereupon and to support such a wafer at an elevated location relative to the shower-pedestal, i.e., such that there is a gap between the underside of the wafer and the top of the shower-pedestal. Wafer support structures may be either fixed structures, e.g., static, tower-like structures that protrude from the top surface of the shower-pedestal, static, tower-like structures that extend downward from a showerhead positioned above the shower-pedestal, or static cantilevered structures that extend radially inward from the walls of a semiconductor processing chamber, or dynamic structures, e.g., similar structures that are connected with actuators that allow such structures to be moved between different positions, at least one of which correlates with a position in which a wafer may be supported thereby such that a gap exists between the underside of the wafer and the top side of the shower-pedestal. Various examples of wafer support structures are discussed in more detail later in this disclosure.

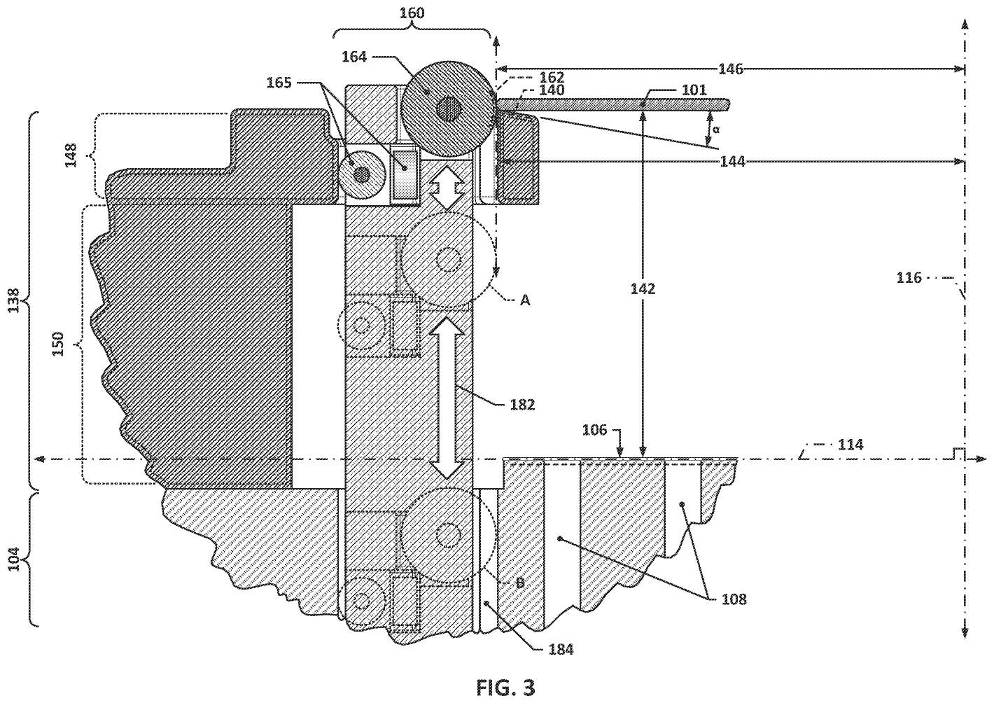

FIG. 3 depicts a detail view of the portion of FIG. 1 that is enclosed within the dash-dot-dash circle (which includes the left wafer support structure 138). As can be seen in FIG. 3, the wafer support structures 138 may each have one or more corresponding wafer support surfaces 140. At least a portion of each wafer support surface 140 may be positioned a first distance 142 away from the first average midplane 114 in a direction perpendicular to the first average midplane and a second distance 144 away from the first reference axis 116 in a direction that is parallel to the first average midplane 114. The first distance 142, for example, may be on the order of several to tens of millimeters, while the second distance 144 may, for example, be half of the diameter of the innermost edge of the wafer 101 that the shower-pedestal is designed to be used with. The wafer support surfaces 140 may be non-parallel to the first average midplane 114, e.g., at an acute, non-zero angle α with respect to the first average midplane, such as an angle greater than 0° and less than or equal to 15°.

A plurality of wafer-centering features 160 may also be provided in association with the shower-pedestal 104. The wafer-centering features 160, like the wafer support structures 138, may be positioned at locations that are generally around the first surface 106, e.g., positioned about the first reference axis 116 and radially offset therefrom. In particular, the wafer-centering features 160 may each have one or more centering surfaces 162, at least portions of which are positioned a third distance 146 away from, and face towards, the first reference axis 116 in a direction perpendicular to the first reference axis 116. The third distance 146 may, for example, be in the range of 150.5 mm and 150 mm for systems that process 300 mm wafers. In some implementations, the wafer-centering surfaces may have portions thereof that form an angle of less than 45° with respect to the first reference axis 116. In some further such implementations, the wafer-centering surfaces may have portions thereof that form an acute angle with respect to the first reference axis 116 that is greater than 0° and less than or equal to 30°.

The wafer-centering features 160 in FIGS. 1 through 3 are provided by wheels 164, although other wafer-centering features may be used, as discussed later herein. In the particular examples of FIGS. 1 through 3, the wafer-centering features 160 are supported on wheel riser structures 182 that have portions that are able to move upward or downward through a notch (not shown) or hole 184 in the shower-pedestal 104. The wafer support structures 138 in this example also have openings therethrough that allow the wheel riser structures 182 to pass therethrough, although other implementations may forego such features.

The wheel riser structures 182 may be connected with one or more wheel riser support structures 180, e.g., such as an annular ring that extends around the stem 105. The wheel riser support structure(s) 180 may, in turn, be connected with one or more vertical lift mechanisms 178, e.g., one or more linear actuators, that may be controllably actuated so as to cause the one or more vertical lift mechanisms 178 to move between at least a first configuration and a second configuration. The one or more vertical lift mechanisms may, in aggregate, support the wheel riser structures 182 and thus the wheels 164. In the first configuration, at least a portion of each wheel is farther from the first average midplane 114 than the wafer support surfaces 140 (or at least from the portions thereof that are located at the first distance 142 from the first average midplane 114 and the second distance 144 from the first reference axis 116). As shown in FIG. 3, the wheel 164 is positioned in a location consistent with the one or more vertical lift mechanisms 178 being in the first configuration. As is evident, approximately half of the wheel 164 is further from the first average midplane 114 than the wafer support surface 140, although more or less of the wheel 164 may do so as well (although at least some of the wheel 164 will still do so).

The wafer 101 is shown in FIGS. 1 through 3 in a perfectly centered condition, e.g., centered on the first reference axis 116. However, if the wafer 101 is lowered onto the wafer support structures 138 slightly off-center from the first reference axis 116, the edge of the wafer 101 may come to rest on the wheel 164. The friction between the wheel 164 and the wafer 101, combined with the weight of the wafer 101, may induce a torque on the wheel 164 that causes the wheel 164 to rotate (with respect to the orientation of FIG. 3) in a clockwise manner. The wafer 101 may remain in contact with the wheel 164 as it rotates, thereby causing the wafer 101 to move downward and also radially inward towards the first reference axis 116. When the edge of the wafer 101 eventually comes to rest on the wafer support surface 140, the wafer will be centered, or at least more centered, on the first reference axis 116 than it was prior to the wheel 164 rotation. If there are at least three wafer-centering features 160 located at spaced apart, e.g., ˜120° angular spacing, locations about the first reference axis 116, then such wafer-centering features 160 may act to center the wafer 101 regardless of in what direction the wafer 101 is misaligned in with respect to the first reference axis 116.

When the one or more vertical lift mechanisms 178 are in the second configuration, each wheel 164 may be in between the first average midplane 114 and where that wheel 164 was when the one or more vertical lift mechanisms were in the first configuration, i.e., closer to the first average midplane 114 than it was when the one or more vertical lift mechanisms were in the first configuration. The dotted outline of the wheel 164, wheel riser structure 182, and guide wheels 165 labeled “A” in FIG. 3 depicts an example location of such components that is consistent with the one or more vertical lift mechanisms being in the second configuration. It will be understood, however, that such components may be in any of a number of other locations as well, e.g., positioned such that the wheel 164 is still within the opening of the wafer support structure 138. For example, the wheel 164 may be positioned such that the portion of the wheel that is furthest from the first average midplane is approximately even with the portion of the wafer support structure that is furthest from the first average midplane or approximately even with the wafer 101 (when present). In another example, the wheel 164 may be positioned such that the portion of the wheel 164 that is closest to the first average midplane 114 is tangent to, or at least very close to, the first average midplane 114.

It will also be appreciated that the wafer 101 may first be placed on the wafer support structures 138 with the one or more vertical lift mechanisms 178 in the second configuration and the one or more vertical lift mechanisms 178 may then be caused to transition to the first configuration after the wafer 101 is resting on the wafer support structures 138. In such implementations, the wafer may be nudged radially inward, closer to being centered on the first reference axis 116, by the upward movement of the wheels 164 that arises from such motion.

In some implementations, such as the one depicted in FIGS. 1 through 3, the wheel riser structures 182 may incorporate one or more guide wheels 165. The guide wheels 165 may be configured to help position the wheel riser structures 182 relative to the wafer support structures 138 so as to more precisely locate the wheels 164 relative to the first reference axis 116, thereby increasing wafer centering accuracy. The guide wheels 165 may, for example, contact interior surfaces of the opening through the wafer support structures 138 as the one or more vertical lift mechanisms 178 transition from the second configuration to the first configuration, thereby causing portions of the wheel riser structures 182 to translate through the openings in the wafer support structures 138. The depicted implementation features three guide wheels 165—one that rolls about an axis that is perpendicular to the page and that guides the wheel riser structure 182 towards the first reference axis 116 and two that are positioned on opposite sides of the wheel riser structure and that roll about axes that are parallel to the page. The latter two guide wheels 165 may act to guide the wheel riser structure 182 in directions that are parallel to the rotational axis of the other guide wheel 165 (i.e., in directions perpendicular to the page). It will be appreciate that a fourth guide wheel may also be included in some implementations, e.g., to guide the wheel riser structure 182 radially outward from the first reference axis 116 in the event that the wheel riser structure 182 is too close thereto. In some implementations, the wheel 164 may serve such a purpose and act as a guide wheel 165 as it passes through the opening in the wafer support structure 138, but in other implementations, a separate guide wheel 165 may be provided for this purpose.

It will also be understood that fewer than three guide wheels 165 may be provided as well. For example, the two side guide wheels 165 (which rotate about axes perpendicular to the axis of rotation of the wheel 164) may, in some instances, be omitted with little impact on centering performance, leaving only a single guide wheel 165 (or two guide wheels) to guide the wheel riser structure 182 radially towards or away from the first reference axis 116.

It will be further understood that guide wheels 165 may additionally or alternatively be placed lower on the wheel riser structure 182 such that the guide wheels 165 engage with the interior surfaces of the notch or hole 184 in the shower pedestal instead of, or in addition to, the interior surfaces of the opening in the wafer support structure 138. It will also be appreciated that the guide wheels 165 may be placed within the shower-pedestal 104 and/or the wafer support structure 138 (and thus remain fixed in place—although rotatable—as the wheel riser structure 182 moves) and configured to contact the wheel riser structure 182 as it translates.

Furthermore, as discussed earlier, some implementations may not utilize any guide wheels 165, e.g., be unguided (or at least not guided by contact with the wafer support structure 138 and/or the shower-pedestal 104).

In some implementations, the vertical lift mechanism(s) may be further configured to transition between at least the first and second configurations and a third configuration. When the one or more vertical lift mechanisms are in the third configuration, the first average midplane 114 may be located in between the wafer support surfaces 140 and at least a portion of each wheel 164. In other words, the wheels 164 may be at least partially retracted below the level of the first average midplane 114. The dotted outline of the wheel 164, wheel riser structure 182, and guide wheels 165 labeled “B” in FIG. 3 depicts an example location of such components that is consistent with the one or more vertical lift mechanisms being in the third configuration. In some such implementations, the first average midplane 114 may be located in between the wafer support surfaces 140 and all of each wheel 164, e.g., each wheel 164 may be retracted entirely within the shower-pedestal 104. In FIG. 3, white double-ended arrows indicate potential movement or transitions between the first and second configurations and the second and third configurations.

It will be understood that in some implementations, the one or more vertical lift mechanisms 178 may only transition between first and second configurations, with the wheels 164 being located at least partially between the first average midplane 114 and, for example, a plane that is co-planar with the underside of the wafer 101 during wafer processing operations. In other implementations, the one or more vertical lift mechanisms 178 may further transition from the second configuration to the third configuration to completely retract the wheels 164 into the shower-pedestal 104, which may better protect the wheels 164 (e.g., from exposure to potential deposition or etch gases that may cause the diameter of the wheels 164 to change, thereby affecting wafer centering accuracy).

The ability to move the wheels 164 between different elevations with respect to the first average midplane 114 and the first surface 106 allows the wheels 164 to be used to help center the wafer 101 but then be moved out of the way to facilitate wafer processing operations. For example, once the wafer 101 is placed and centered on the wafer support structures 138, the shower-pedestal 104 may be caused to move upward so as to approach a showerhead (not shown) that is located above the shower-pedestal. In some instances, the showerhead may support a ring structure, e.g., a focus ring, that may be configured to rest on, and be supported by, the wafer support structures 138 when the shower-pedestal is brought sufficiently close to the showerhead. Such ring structures may be generally annular in shape and may have an interior edge that has a radius that is less than the diameter of the wafer so as to overlap the outer edge of the wafer. By making the wheel riser structures 182 movable/retractable, the wheels 164 may be caused to move to a lower position relative to the wafer support structures 138 prior to, or in tandem with, the movement of the shower-pedestal 104 so as to cause the ring structure to come into contact with the wafer support structures 138. This avoids potential interference/contact between the wheels 164 and/or wheel riser structures 182 and the ring structure and/or showerhead. It also avoids or reduces the potential for variations in radial flow conductance (in either or both of the space between the wafer and the showerhead or the wafer and the shower-pedestal) that may occur around the perimeter of the wafer due to the presence of the wheel riser structures 182 and/or the wheels 164.

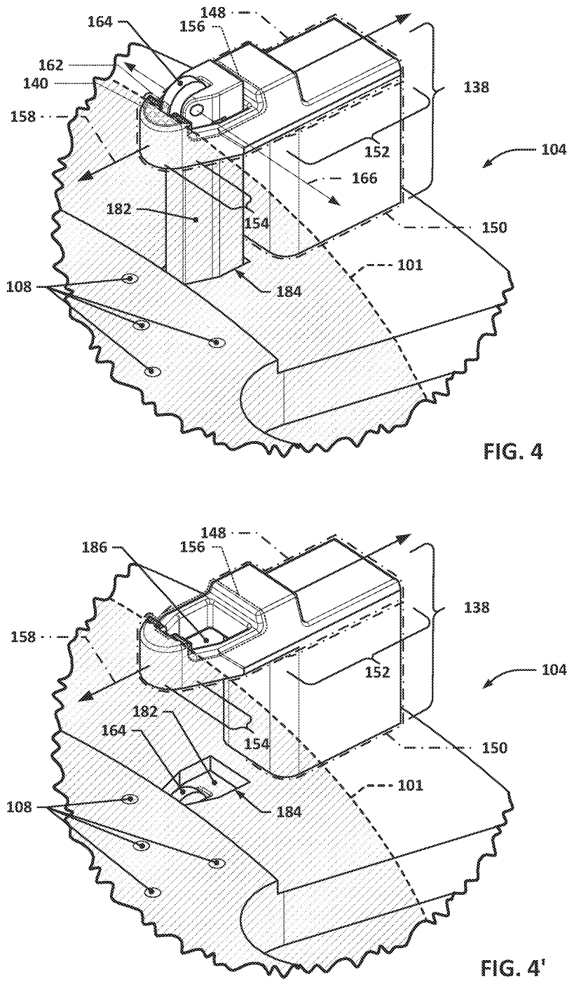

Various types of wafer support structures 138 and wafer-centering features 160 may be used in various implementations. FIGS. 4 through 7 depict four examples of such elements to give a sense of different types of such structures, although it will be appreciated that other variations of such structures will fall within the scope of this disclosure as well. The wafer 101 is shown as a portion of a shaded transparent circle in FIGS. 4 through 7 for reference.

FIG. 4 depicts an isometric detail view of the implementation of the wafer-centering feature 160 and wafer support structure 138 shown in FIGS. 1 through 3; FIG. 4′ shows the same implementation but with the wheel 164 retracted into the shower-pedestal 104 (e.g., as it may be when the one or more vertical lift mechanisms 178 are in the third configuration). As such, many of the elements depicted have already been discussed above.

As can be seen more clearly in FIG. 4, some implementations of the wafer support structure 138 may generally have two main portions—a riser portion or structure 150 and a cantilever beam portion or structure 148. The riser structure 150 and the cantilever beam structure 148 may be provided by separate components or, as shown, be different parts or portions of a single component. The cantilever beam structure 148 may be supported by the riser structure 150 relative to the shower-pedestal 104. A proximal end 152 of the cantilever beam structure 148 may be connected with the riser structure 150, and the wafer support surface(s) 140 of the wafer support structure 138 may be located at a distal end 154 of the cantilever beam structure 148. The cantilever beam structure 148 may generally have a long axis 158 that is oriented towards/away from the first reference axis 116, e.g., along a radius that extends from the first reference axis 116. In some implementations, the cantilever beam structure 148 may extend radially inward from the corresponding riser structure 150 and towards the first reference axis 116.

More clearly visible in FIG. 4′ is opening 186 through the cantilever beam structure 148 of the wafer support structure 138. As can be seen, the opening 186 is sized to allow the wheel riser structure 182 and the wheel 164 to pass at least partially therethrough, thereby allowing the wheel 164 to be moved into a position (as shown in FIG. 4) where it can contact the wafer 101 and act to center the wafer 101 on the first reference axis 116.

Also more clearly visible in FIG. 4 are the wafer support surface 140 and the centering surface 162. In the case of the wheel 164, the centering surface 162 may actually be the entire circular outer surface of the wheel 164, although only the portion of that surface that is generally closest to the first reference axis 116 may actually act to center the wafer 101. As the wheel 164 rotates about axis 166, different portions of the outer surface of the wheel 164 may act as the centering surface 162.

Another feature that is more clearly visible in FIGS. 4 and 4′ is channel 156 that is provided in a side or surface of the cantilever beam structure 148 that faces away from the first average midplane 114. In some implementations, the channel 156 may be provided in the cantilever beam structure 148, or in the wafer support structure 138 more generally, to help prevent or reduce particulate contamination of the wafer 101 in the event that the wafer support structure 138 is used to support a ring structure, as discussed earlier. The channel 156 may generally be located further from the first reference axis than the wafer support surface 140, e.g., between the wafer support surface 140 and at least a portion of the riser structure 150, and may extend in a direction that is transverse to the long axis 158 and parallel to the first average midplane 114. In the event that the wafer support structure 138 is used to support a ring structure, such as a focus ring, the channel 156 may receive an annular wall that may protrude from the underside of the ring structure. The channel 156 may be sized such that it does not contact the annular wall, and the wafer support structure 138 may be configured such that it contacts the ring structure at a location outboard of the annular wall. Thus, any particulates that are generated through contact between the ring structure and the wafer support structure 138 may be prevented from having a direct path of travel to the wafer by the annular wall. This may act to reduce the chances of, or prevent entirely, such particulates reaching the wafer and potentially contaminating it. The channel 156 may, in some implementations, be at least 0.75 mm or at least 1 mm deep with respect to one or both ends of the channel 156.

The implementation of FIGS. 1 through 4′ features wafer-centering features 160 and wafer support structures 138 that are located at the same angular positions about the first reference axis 116. As a result, the wheel riser structures 182 generally need to pass through the cantilever beam structures 148 by way of the openings 186 (although a notch could also be used in place of the opening 186, if desired). However, the wafer-centering features 160 do not necessarily need to be located at the same angular positions about the first reference axis 116 as the wafer support structures 138.

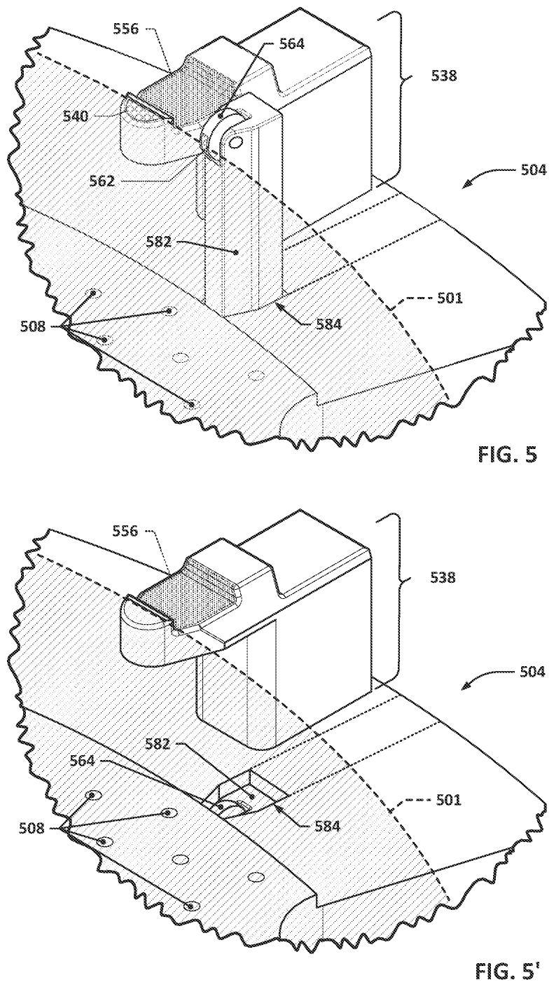

FIG. 5 shows an example implementation in which wafer-centering features 560 are circumferentially offset, i.e., have different angular positions, with respect to a first reference axis 516 than wafer support structures 538. FIG. 5′ shows the same implementation as FIG. 5, but with wheel riser structures 582 retracted into shower-pedestal 504. Many of the structures and features shown in FIGS. 5 and 5′ are generally similar to structures and features shown in FIGS. 1 through 4′. Accordingly, the descriptions and discussion relating to such structures and features provided previously with regard to FIGS. 1 through 4′ may be understood to be equally applicable to the corresponding structures and features in FIGS. 5 and 5′, unless otherwise indicated or suggested by the discussion below. Such corresponding structures and features in FIGS. 5 and 5′ are indicated using callouts having the same last two digits as are used in the callouts of such structures or features in FIGS. 1 through 4′.

As shown in FIG. 5, the wafer support structure 538 is circumferentially offset from the wheel riser structure 582, i.e., at a different angular position relative to the first reference axis (not shown, but see earlier Figures) than the wheel riser structure 582. Thus, the notch or hole 584 through the shower-pedestal 504 is in a different location relative to the wafer support structure 538 than it is in FIG. 4′ (for clarity, dotted lines extending radially outward from the hole 584 indicate an example of where material of the shower-pedestal 504 may be removed or omitted to turn the hole 584 into a notch). Additionally, the wafer support structure 538 in this example no longer has an opening therethrough, e.g., such as opening 186, as it is no longer the case that the wheel riser structure would pass through the cantilever beam structure of the wafer support structure 538. The channel 556 is also potentially more discernible in FIGS. 5 and 5′; shading has been added to better highlight its extent.

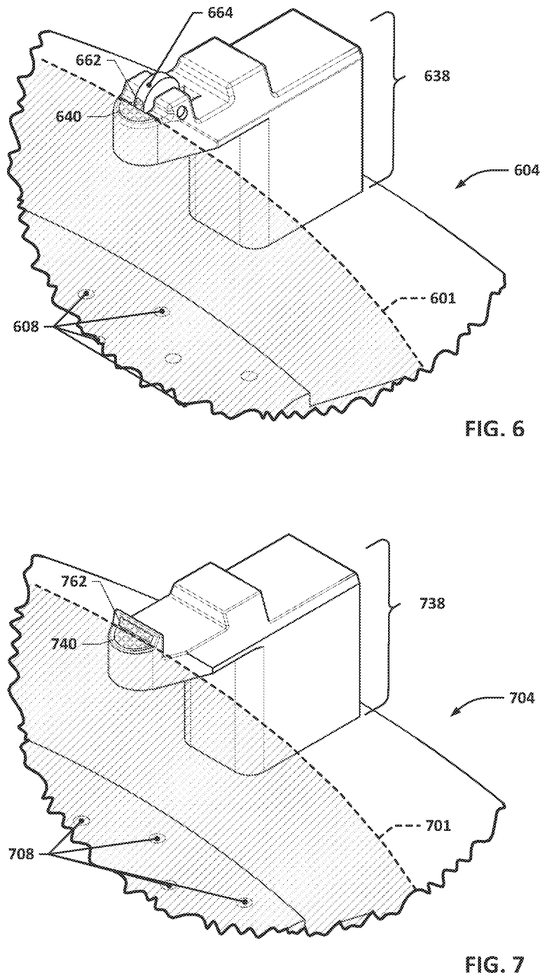

In the above examples, the wafer-centering features have been provided by wheels that are able to be moved vertically through use of one or more vertical lift mechanisms. However, in some implementations, the wafer-centering features that are used may be supported by, and fixed in space relative to, the wafer support structures (at least with regard to vertical movement). FIG. 6 depicts an example of such an implementation. Many of the structures and features shown in FIG. 6 are generally similar to structures and features shown in FIGS. 1 through 5′. Accordingly, the descriptions and discussion relating to such structures and features provided previously with regard to FIGS. 1 through 5′ may be understood to be equally applicable to the corresponding structures and features in FIG. 6 unless otherwise indicated or suggested by the discussion below. Such corresponding structures and features in FIG. 6 are indicated using callouts having the same last two digits as are used in the callouts of such structures or features in FIGS. 1 through 5′.

In FIG. 6, the wheel 664 is supported by the wafer support structure 638 rather than by a wheel riser structure. As a result, the wheel 664 remains at a fixed elevation with respect to the wafer support structure 638, e.g., permanently in a position similar to that in which the wheel 164 is in when the one or more vertical lift mechanisms 178 discussed earlier are in the first configuration.

In some implementations, the wafer-centering features may be provided by non-wheel structures. For example, the wafer-centering features may instead be static structures, e.g., protrusions, that have sloped surfaces, e.g., structures having a sloped surface that provides the centering surface. FIG. 7 depicts an example implementation of a wafer support structure 738 that has a wafer-centering feature that includes a protrusion that extends upward from the wafer support surface 740 and has a sloped surface that provides centering surface 762.

Many of the structures and features shown in FIG. 7 are generally similar to structures and features shown in FIGS. 1 through 5′. Accordingly, the descriptions and discussion relating to such structures and features provided previously with regard to FIGS. 1 through 5′ may be understood to be equally applicable to the corresponding structures and features in FIG. 7 unless otherwise indicated or suggested by the discussion above. Such corresponding structures and features in FIG. 7 are indicated using callouts having the same last two digits as are used in the callouts of such structures or features in FIGS. 1 through 5′.

It will also be appreciated that the static wafer-centering features, e.g., as shown in FIG. 7, may also be implemented in place of wheels on wafer-centering features that have wheel riser structures (or, more appropriately, static-feature riser structures that are similar to wheel riser structures) that may be moved up and down via one or more vertical lift mechanisms.

In implementations where the wafer-centering features are not able to be moved up and down relative to the wafer support structures, the wafer-centering features may protrude into space that may need to be occupied by other components during some phases of operation. Such other components may include, for example, a focus ring and/or a showerhead.

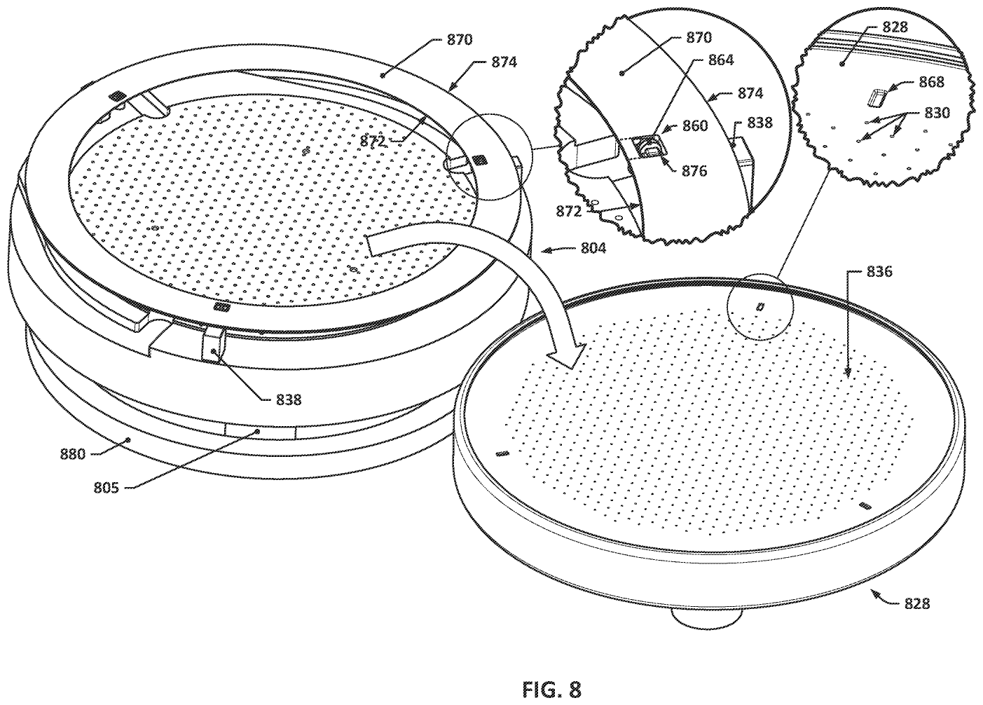

FIG. 8 depicts a view of an example shower-pedestal 804, as well as a showerhead 828 and focus ring 870. No wafer is shown in FIG. 8. In FIG. 8, the showerhead 828 is not shown in its normal position above the shower-pedestal 804, but is instead flipped over upside-down and relocated off to the side of the shower-pedestal 804, much as if the shower-pedestal 804 and the showerhead 828 were the covers of a book that had been opened. The focus ring 870 is shown being supported by wafer support structures 838 (although in some implementations, the focus ring 870 may be captured within a feature of the showerhead 828 such that it would generally not be able to be positioned separately from the showerhead, as shown).

Many of the structures and features shown in FIG. 8 are generally similar to structures and features shown in FIGS. 1 through 3, although the wafer support structure 838 and the wafer-centering feature used are similar to those shown in FIG. 6. Accordingly, the descriptions and discussion relating to such structures and features provided previously with regard to FIGS. 1 through 3 and FIG. 6 may be understood to be equally applicable to the corresponding structures and features in FIG. 8, unless otherwise indicated or suggested by the discussion below. Such corresponding structures and features in FIG. 8 are indicated using callouts having the same last two digits as are used in the callouts of such structures or features in FIGS. 1 through 3 and 6.

As can be seen in FIG. 8, the showerhead 828 has a large number of second gas distribution ports 830 distributed across a second surface 836 of the showerhead 828. The second gas distribution ports 830 may be used to distribute process gases across the wafer (when present) during processing operations. Such process gases may, in some implementations, be non-reactive gases such as a noble gas (argon (Ar), for example) or nitrogen (N₂) that may shield the top side of the wafer from potential exposure to the processing gases used to process the underside of the wafer.

The focus ring 870 may be designed to overlap the edge of the wafer (when present) to provide a mechanical barrier to potential diffusion of process gases from the underside of the wafer to the top side of the wafer. The focus ring 870 may have an inner edge 872 and an outer edge 874 that are nominally circular. In some implementations, the inner edge may have a diameter that is less than twice the third distance (between the centering surfaces and the first reference axis, e.g., less than the diameter of the wafer), and the outer diameter may have a diameter that is larger than twice the third distance.

As can be seen in FIG. 8, both the focus ring 870 and the showerhead 828 include features that are provided to accommodate the presence of wafer-centering features 860, e.g., wheel 864 and a portion of the wafer support structure 838 that supports the axle thereof that protrude above the elevation where the top of the wafer would normally be.

The focus ring 870 has an opening 876 that is proximate the inner edge 872 and sized large enough that the protruding portions of the wheel 864 and the portion of the wafer support structure 838 are able to pass therethrough without contacting the focus ring 870 when the focus ring 870 is supported by the wafer support structures 838. The openings 876 may also be notches that extend from the inner edge 872 outward (as suggested by the dotted lines visible between the opening 876 and the inner edge 872 in the enlarged detail view shown). The showerhead 828 similarly has a plurality of recesses 868 in it that correspond in number to the number of wafer-centering features 860 that are used, e.g., three. The recesses 868 are positioned such that the portions of the wafer-centering features 860 that may protrude through the focus ring 870 are able to extend into the recesses, thereby preventing the showerhead 828 from bottoming out on, and contacting, the wafer-centering features 860. The recesses 868 and/or the openings 876 may generally be positioned such that second reference axes (not shown) that are parallel to the first reference axis 816 and that pass through a center of, for example, the wheels 864 or other wafer-centering feature, e.g., a protrusion such as shown in FIG. 7, also pass through corresponding openings 876 and/or recesses 868.

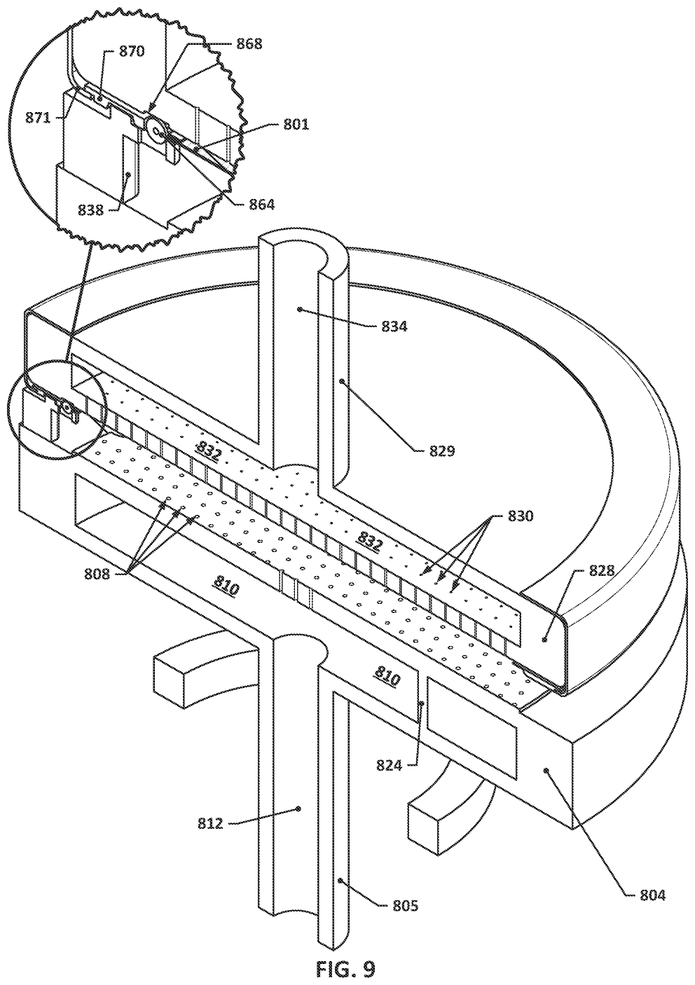

For further clarity, reference is made to FIG. 9, which depicts the showerhead 828 and the shower-pedestal 804 of FIG. 8 positioned as they might be during actual wafer processing operations (no wafer is depicted in the main view, although a wafer is shown in dotted lines and cross-hatching in the detail view). As can be seen, the focus ring 870 is supported by the wafer support structure 838. A ring support collar 871 that extends around the showerhead 828 has a flange that extends inward towards the focus ring 870. The flange may have an inner diameter that is slightly smaller than that of the focus ring 870, thereby allowing the focus ring 870 to rest on the flange and thus be indirectly supported by the showerhead 828 when not otherwise supported by the wafer support structures 838. The distance between the surface of the flange that supports the focus ring 870 and the underside of the showerhead 828 may be sized so as to be larger than the thickness of the portion of the focus ring 870 that rests on the flange, thereby allowing the focus ring 870 to be able to move freely in the vertical direction over a limited range of motion. This may ensure that the focus ring 870 is able to rest entirely on the wafer support structures 838, which may allow the gap between the focus ring 870 and the wafer 801 to be more tightly controlled.

As can be seen in FIG. 9, the recess 868 is located and sized such that the wheel 864 is able to extend thereinto without contacting the showerhead 828 while the focus ring 870 is resting on the wafer support structures 838.

Also visible in FIG. 9 are a second plenum 832 that fluidically connects the second gas distribution ports 830 with a second gas inlet 834. The second gas inlet 834 may be used to introduced one or more process gases into the showerhead 828 for distribution across the top of the wafer 801. Also shown in FIG. 9 are a stem 805, a first gas inlet 812, and first gas distribution ports 808 of the shower-pedestal 804.

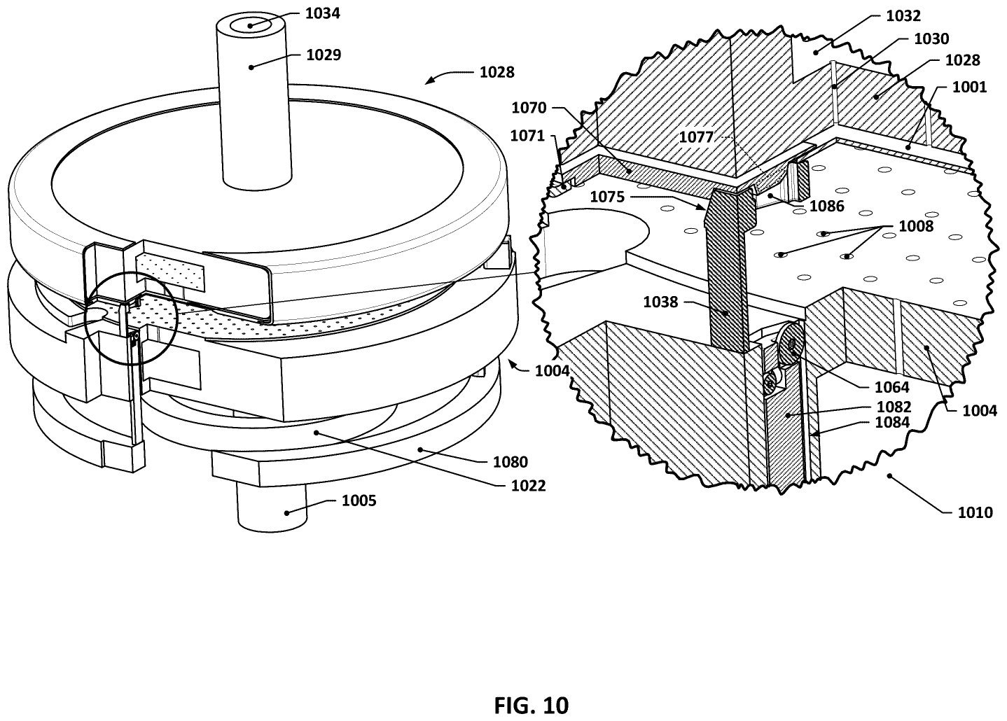

FIG. 10 depicts an example of a showerhead 1028 and a shower-pedestal 1004 that includes wafer support structures 1038 that are similar to those shown in FIGS. 4 and 4′. The structures shown in FIG. 10 have been cut away to illustrate two orthogonal section planes of a wafer support structure 1038 that is connected with the shower-pedestal 1004. Many of the structures and features shown in FIG. 10 are generally similar to structures and features shown in earlier-discussed Figures. Accordingly, the descriptions and discussion relating to such structures and features provided previously with regard to other Figures may be understood to be equally applicable to the corresponding structures and features in FIG. 10 unless otherwise indicated or suggested by the discussion below. Such corresponding structures and features in FIG. 10 are indicated using callouts having the same last two digits as are used in the callouts of such structures or features in previous Figures.

The shower-pedestal 1004 that is depicted has a first plenum 1010 that may provide one or more processing gases to the underside of a wafer 1001 via a plurality of first gas distribution ports 1008. Such process gases may be provided to the shower-pedestal 1004 via a first gas inlet that is located in shower-pedestal stem 1005. The wafer 1001 may be supported on a plurality of wafer support structures 1038, e.g., wafer support structures that are similar to the wafer support structures 138 discussed earlier. Such wafer support structures 1038 may have openings 1086 that allow a wheel riser structure 1082 and wheel 1064 (shown retracted into a hole 1084 in the shower-pedestal 1004 here) to be extended therethrough so as to cause the wafer 1001 to be centered or more centered on a first reference axis (not shown here, but see earlier discussion thereof for other implementations).

The showerhead 1028 in FIG. 10 has a second plenum 1032 that may be provided one or more processing gases (which may be gases that are inert or non-reactive with respect to the processing gases that may be delivered from the shower-pedestal 1004) via a second plenum 1032. The second plenum 1032 may be provided such one or more processing gases via a second gas inlet 1034 located in showerhead stem 1029 and then flow such processing gases towards the top side of the wafer 1001 via second gas distribution ports 1030.

Also visible in FIG. 10 is focus ring 1070, which may rest on ring support collar 1071 when the shower-pedestal 1004 is low enough that the focus ring 1070 is not able to rest on the wafer support structures 1038. When the shower-pedestal 1004 is in a sufficiently elevated state, the focus ring 1070 may come to rest on the wafer support structures 1038. The wafer support structures 1038 may, for example, have tapered sides (as shown) that may serve as ring support surfaces 1075. The ring support surfaces 1075 may, for example, contact similarly sloped sides on the underside of the focus ring 1070, e.g., the focus ring 1070 may have recesses or pockets 1067 on the bottom surface that are positioned so as to align with the wafer support structures 1038, and the sides of these recesses or pockets may be sloped so as to engage with sloped sides of the wafer support structures 1038. Such sloped ring support surfaces 1075 may act to center the focus ring 1070 on the first reference axis when it comes to rest on the wafer support structures 1038. For example, the set of opposing sloped ring support surfaces 1075 for each wafer support structure 1038 may be symmetric about a plane that is coplanar with the first reference axis, thereby causing the corresponding mating feature on the focus ring to be centered on the symmetry plane when placed into contact with the ring support surfaces 1075. When three sets of opposing sloped ring support surfaces 1075 are arranged about the first reference axis, the resulting centering effect may cause the focus ring to center itself on the first reference axis (and thus the wafer 1001).

FIG. 10 also depicts an annular wall 1077 on the underside of the focus ring 1070. The annular wall may, as noted earlier, extend down into a channel (not called out, but see earlier implementations) in the cantilever beam structure of the wafer support structure 1038. As can be seen in FIG. 10, any particulates that are generated through contact of the ring support surfaces 1075 with the focus ring 1070 are blocked from having a direct path to the wafer 1001 by the annular wall 1077.

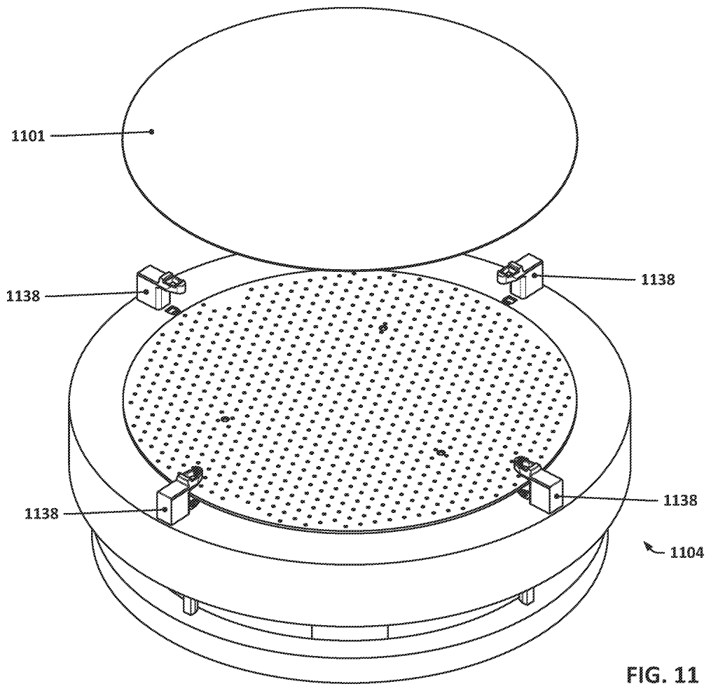

As noted earlier, shower-pedestals such as those discussed above may have other numbers of wafer support structures. For example, while FIGS. 1, 2, and 8 through 10 depict example shower-pedestals having three wafer support structures, other implementations may have a different number of wafer support structures. For example, FIG. 11 depicts an isometric view of a shower-pedestal 1104 that is similar to the shower-pedestal 804, except that it has four wafer support structures 1138 (as compared to the three wafer support structures 838 of the shower-pedestal 804). While implementations with three wafer support structures may provide an inherently stable support for a wafer supported thereby, implementations such as the shower-pedestal 1104 may be better adapted to supporting wafers 1101 that may exhibit bilateral symmetry about two orthogonal axes. For example, some semiconductor processing operations may cause a wafer to bow about two orthogonal axes, resulting in the wafer taking on a saddle shape. As a consequence thereof, the perimeter of such a wafer may have “high” points at diametrically opposed locations, e.g., at 0° and 180°, and “low” points at two other diametrically opposed locations 90° out of phase from the high points, e.g., at 90° and 270°. The shower-pedestal 1104, since it has four wafer support structures 1138, can be used to support such a wafer at locations in between the high and low points along the wafer edge (these locations may generally all be at the same elevation).

It will be understood that all of the implementations discussed herein and shown in the Figures that exhibit 3-fold radial symmetry (having three wafer support structures, for example) may also be provided in implementations having four-fold radial symmetry, e.g., such as exhibited by the shower-pedestal 1104.

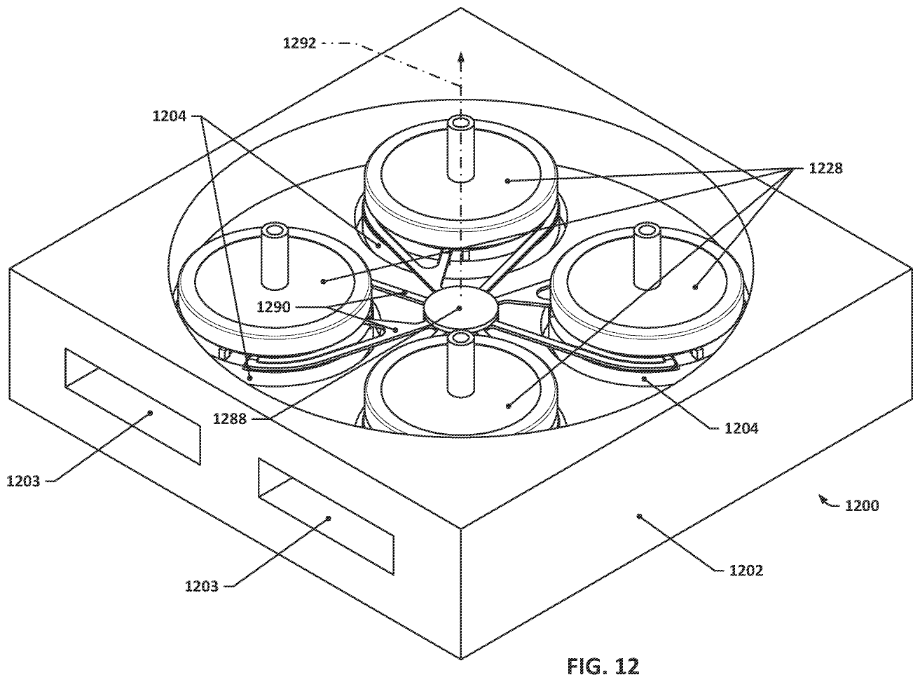

The shower-pedestal and showerhead arrangements discussed above may be implemented in the context of a single-station or multi-station semiconductor processing chamber. FIG. 12 depicts an example four-station semiconductor processing tool. The depicted tool may include a chamber 1202 that includes a rotational indexer 1288 that may controllable so as to rotate about a first rotational axis 1292. The rotational indexer 1288 may have a plurality of forks 1290 that are arranged in a circular array about the first rotational axis 1292 such that the rotational indexer 1288, when rotated about the first rotational axis 1292, causes the forks 1290 to rotate about the first rotational axis 1292 as well. Also arranged in a circular array about the first rotational axis 1292 are four sets of shower-pedestals 1204 and showerheads 1228. The rotational indexer 1288 may generally be configured to rotate between various rotational positions, e.g., a first rotational position in which wafer lift surfaces of a first fork 1290 of the forks 1290 are positioned above a first shower-pedestal of the shower-pedestals, a second rotational position in which the wafer list surfaces of the first fork 1290 are positioned over a second shower-pedestal of the shower-pedestals, and so forth.

The chamber 1202 may have a plurality of wafer load slots 1203 that may, for example, provide an entryway for wafers to be introduced into, or removed from, the chamber 1202. The rotational indexer 1288 may be used to rotate wafers that have been introduced into the chamber 1202 between different shower-pedestals 1204. In implementations with only a single station, the chamber 1202 may be sized commensurately smaller, and only one shower-pedestal 1204 and showerhead 1228 may be located within the chamber 1202. The rotational indexer 1288 and the forks 1290 may also be omitted.

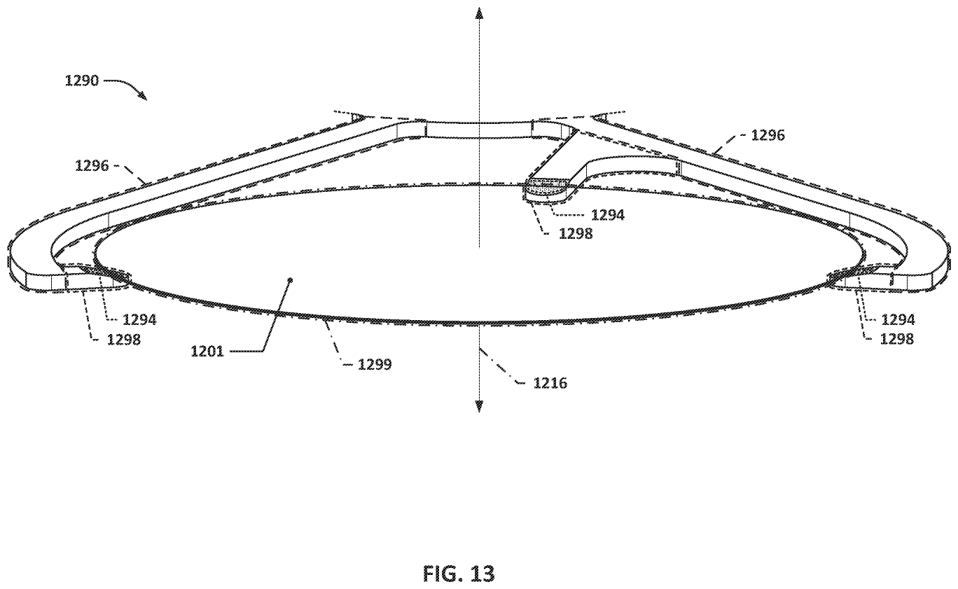

FIG. 13 depicts a perspective view of an example fork 1290 with a wafer 1201 (shown transparent to allow features of the fork 1290 to be seen therethrough). As can be seen in FIG. 13, the fork 1290 has two arms 1296 that extend outward from a hub or spindle of the rotational indexer 1288 (not shown). The arms 1296 may extend at least partially around a circular region 1299 that has a diameter that is sized to be twice the third distance (the third distance as discussed earlier with respect to other implementations, e.g., a distance that is the same or nearly the same as the radius of a wafer that is to be handled using the forks). In some implementations, the arms 1296 may be located entirely outside of the circular region 1299. The circular region 1299 may, for example, be located in a position relative to the fork 1290 such that the circular region 1299 is centered on the first reference axis 1216 when the rotational indexer 1288 is controlled so as to cause the fork 1290 of FIG. 13 to be in a first rotational position, e.g., with the wafer list surfaces thereof positioned above a first shower-pedestal 1204 of the shower-pedestals 1204 in locations that, in theory, would cause the wafer 1201 supported thereby to be centered on the first reference axis thereof.

The arms 1296 may include one or more protrusions 1298 that extend inward towards the first reference axis 1216 and partially into the circular region 1299. The protrusions 1298 may be contiguous with the arms 1296 and may each have a wafer lift surface 1294 that is at a non-parallel angle with respect to the first average midplane. The wafer lift surfaces 1294 may, it will be seen, also extend at least partially into the circular region 1299. The wafer lift surfaces 1294 may, for example, be sloped at an angle with respect to the first average midplane that is greater than 0° and less than or equal to 25°. This allows the fork 1290 to contact the wafer 1201 only along an edge of the wafer 1201, thereby minimizing the amount of contact between the bottom surface of the wafer 1201 and the fork 1290 and reducing the amount of potential particulate generation that may occur.

The various components discussed above may be made from a variety of suitable materials, e.g., materials that are non-reactive or inert with respect to the various processing gases that may be used. For example, one or more of the wheels (if used), static wafer-centering features (if used), wafer support structures, wheel or static structure riser structures (if used), focus ring, shower-pedestal, showerhead, and forks (if used) may be made, in whole or in part, of a ceramic material such as aluminum oxide, silicon nitride, etc.

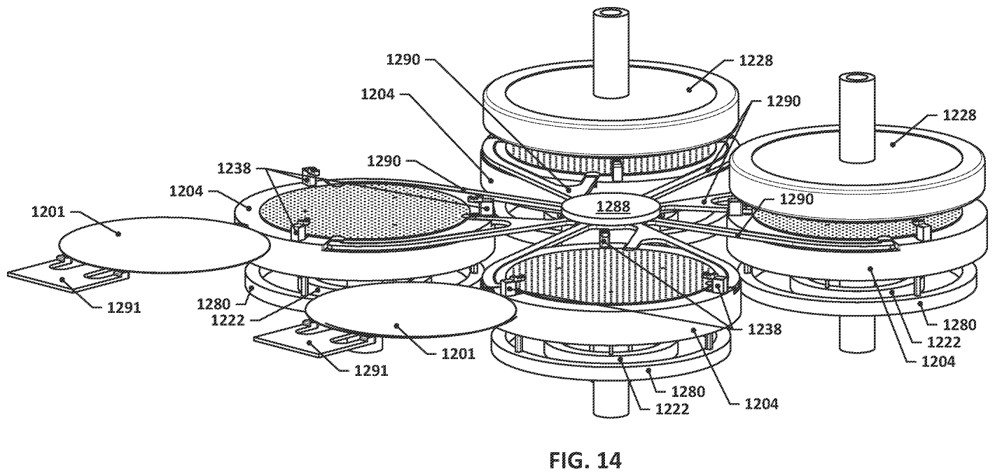

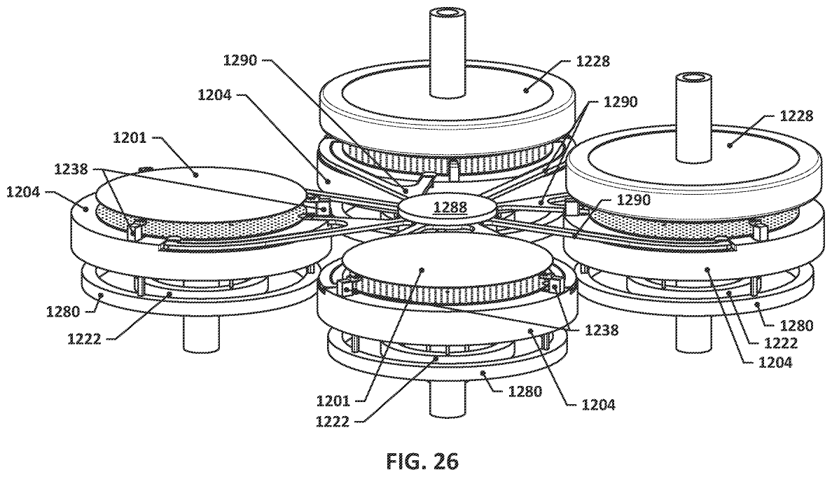

FIGS. 14 through 26 depict an arrangement of four stations similar to those shown in FIG. 12 during various stages of wafer placement and positioning operations. In most of the FIGS. 14 through 26 (although not all), the showerheads 1228 that are closest to where the wafer load slots 1203 are located are omitted from view so as to not obscure the shower-pedestals 1204 positioned therebelow. The chamber 1202 is also omitted from all of FIGS. 14 through 26 to avoid obscuring the features discussed.

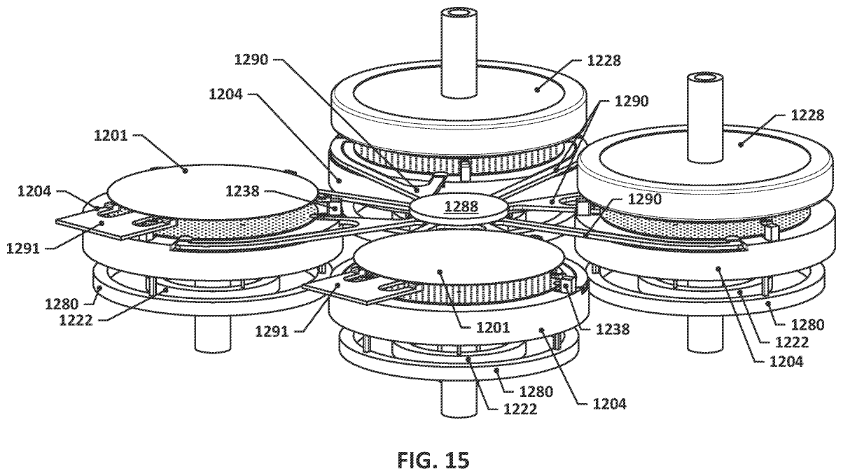

In FIG. 14 two end effectors 1291 are shown supporting wafers 1201. The end effectors 1291 may, similar to forks 1290, have wafer lift surfaces that are sloped at an oblique angle with respect to the first average midplanes or first reference axes of the shower-pedestals 1204. The end effectors 1291 may be attached to one or more robot arms (not shown) that may be controlled so as to inert the end effectors 1291 and the wafers 1201 supported thereby into the chamber 1202 via the wafer load slots 1203, as shown in FIG. 15. In FIG. 15, the wafers 1201 are each nominally centered over a corresponding one of the shower-pedestals 1204 (the showerheads 1228 corresponding to these two shower-pedestals 1204 are not shown in FIGS. 14 through 20).

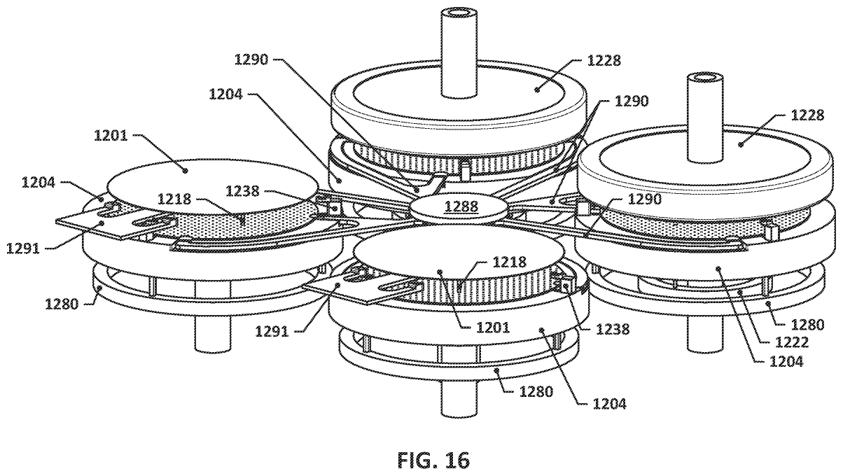

In FIG. 16, lift pins 1218 that are supported by lift pin support structures 1222 have been caused by one or more lift pin actuators (not shown, but see FIG. 14) to extend out of the first surface of the shower-pedestals 1204 where the wafers 1201 are being placed, thereby lifting the wafers 1201 off of the end effectors 1291. As can be seen, the wafers 1201 now no longer rest on the wafer lift surfaces of the end effectors 1291.

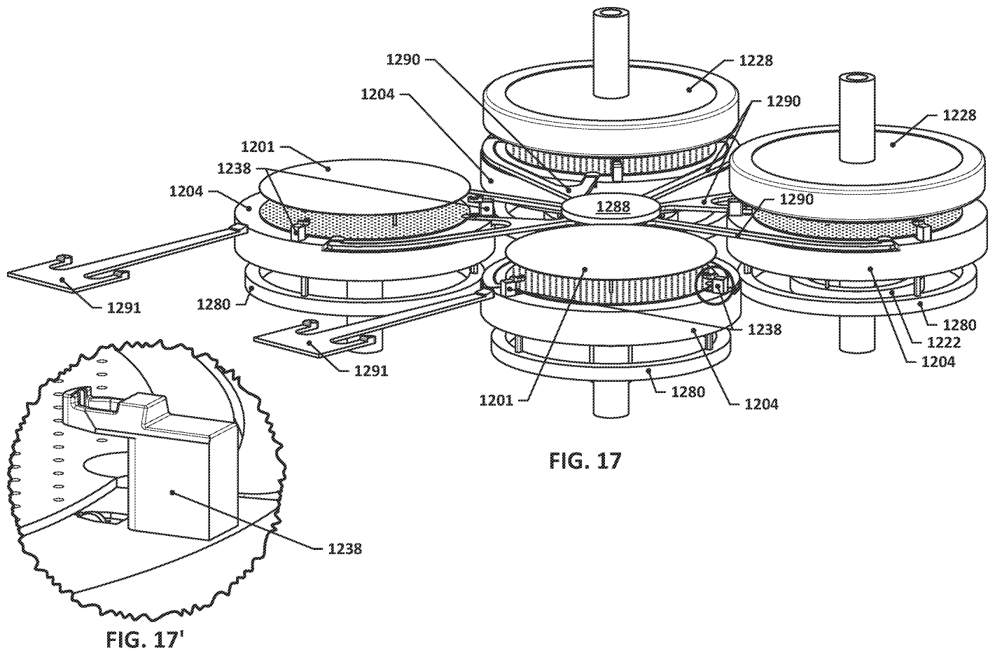

In FIG. 17, the one or more robot arms have been caused to retract from the chamber 1202, leaving the wafers 1201 (supported by the lift pins 1218) behind in the chamber 1202. As seen in the inset detail view 17′, there are a plurality of wafer support structures 1239 positioned at locations on each shower-pedestal 1204 that are similar to those discussed earlier with respect to FIGS. 1 through 3. It will be understood, however, that any suitable wafer support structure 1238 capable of supporting wafer edge contact may be used—including, but not limited to, the examples discussed earlier herein with respect to FIGS. 4 through 7. In this particular example, the wafer-centering features (wheels and wheel riser structures that are able to be extended or retracted from the shower-pedestal 1204) are shown retracted into the shower-pedestals 1204.

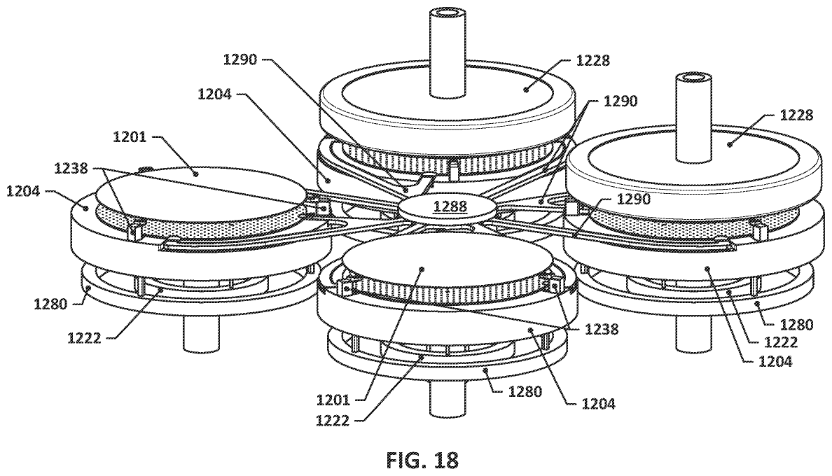

In FIG. 18, the lift pin actuators have been controlled so as to retract the lift pins 1218 back into the shower-pedestal 1204, thereby lowering the wafer 1201 onto the wafer support structures 1238. At this point, the wafers 1201 are nominally centered over each shower-pedestal 1204, but may still benefit from additional centering.

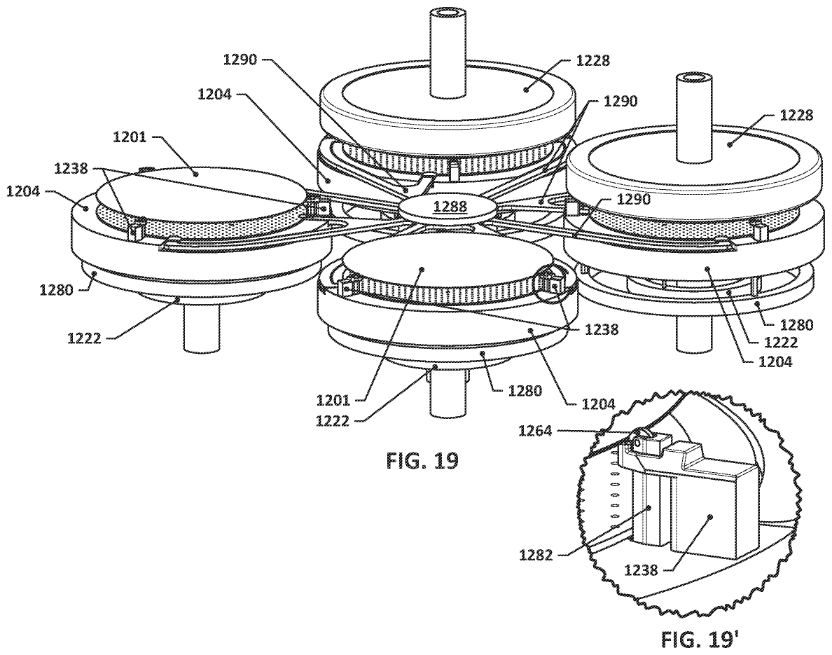

In FIG. 19, one or more vertical lift mechanisms (not shown, but see FIG. 14) have been caused to move wheel riser support structures 1280 vertically upward, thereby causing wheel riser structures 1282 and wheels 1264 to extend upward out of the shower-pedestals 1204 and through openings in the wafer support structures 1238. During such movement, one or more of the wheels 1264 (see detail FIG. 19′) may come into contact with the edges of the wafers 1201 and exert radially inward-directed forces on the wafer 1201s that causes the wafer 1201s to, if not already adequately centered, become more centered on the first reference axes (not shown, but see earlier Figures) for the corresponding shower-pedestals 1204. As noted earlier, in some implementations, the one or more vertical lift mechanisms may be actuated so as to raise the wheel riser structures 1282 and the wheels 1264 prior to the retraction of the lift pins 1218 so that the wafers 1201 come into contact with the wheels 1264 as the lift pins 1218 lower the wafers 1201 onto the wafer support structures 1238.

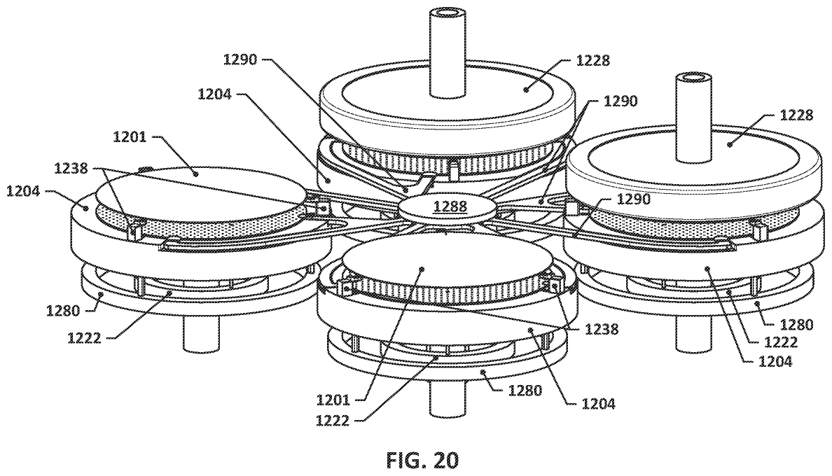

In FIG. 20, the one or more vertical lift mechanisms have been actuated so as to lower the wheel riser structures 1282 and the wheels 1264 back into the shower-pedestals 1204, thereby leaving the wafers 1201 resting on the wafer support structures 1238 in a location that is centered, or more centered, on the first reference axes of the shower-pedestals 1204.

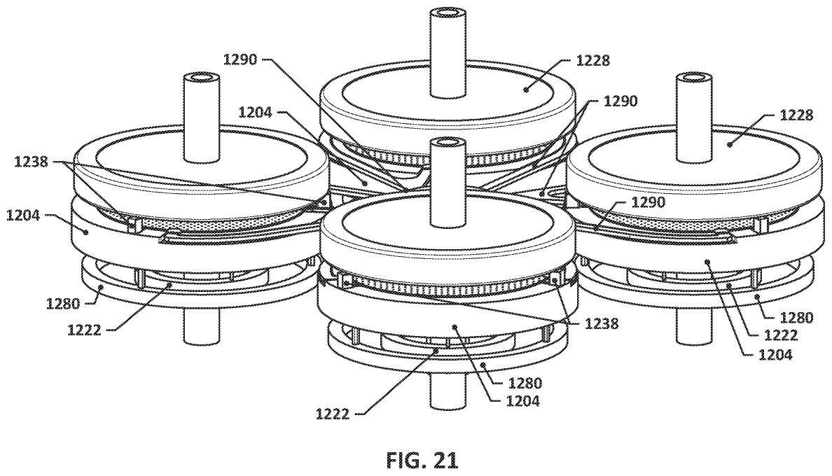

In FIG. 21, the shower-pedestals 1204 have been raised (and/or the showerheads 1228 lowered), e.g., by a corresponding lift mechanism (not shown) so as to cause a gap between the top sides of the wafers 1201 and the undersides of the showerheads 1228 to decrease. While not shown, the gaps between the undersides of the showerheads 1228 and the top sides of the wafers 1201 may be decreased to the point where focus rings supported by the showerheads 1228 may come into contact with the wafer support structures and then be supported thereby at a desired distance from the wafers 1201 (see FIG. 10, for example). One or more process gases may then be caused to flow out of the shower-pedestals 1204, e.g., through the activation of one or more valves, and towards the undersides of the wafers 1201 for one or more periods of time, thereby causing material to be deposited on, or etched from, the underside of the wafers 1201. At the same time, a non-reactive or inert gas, e.g., a noble gas such as argon or a gas such as nitrogen, may be flowed through the showerheads 1228 and onto the top sides of the wafers 1201 and focus rings to prevent undesired deposition or etching from occurring on the top sides of the wafers 1201.

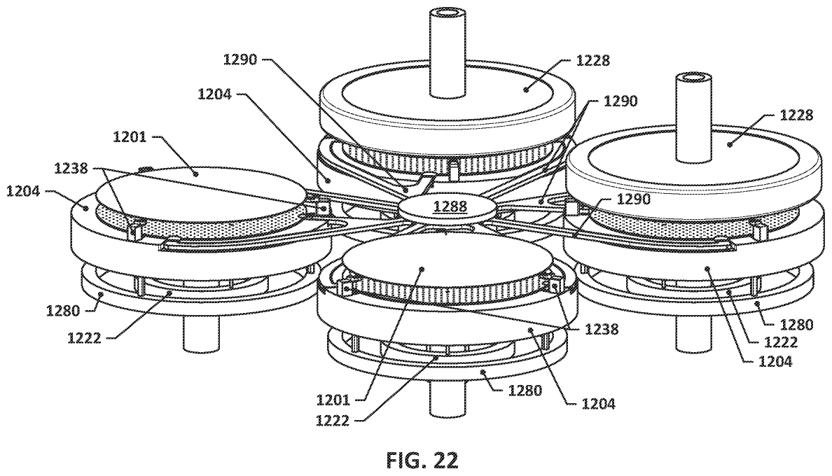

Once processing operations are complete for the wafers 1201 at a given station, the shower-pedestals 1204 may be retracted (and/or the showerheads 1228 raised) so as to return the semiconductor processing tool to a state similar that that shown in FIG. 20, as shown in FIG. 22.

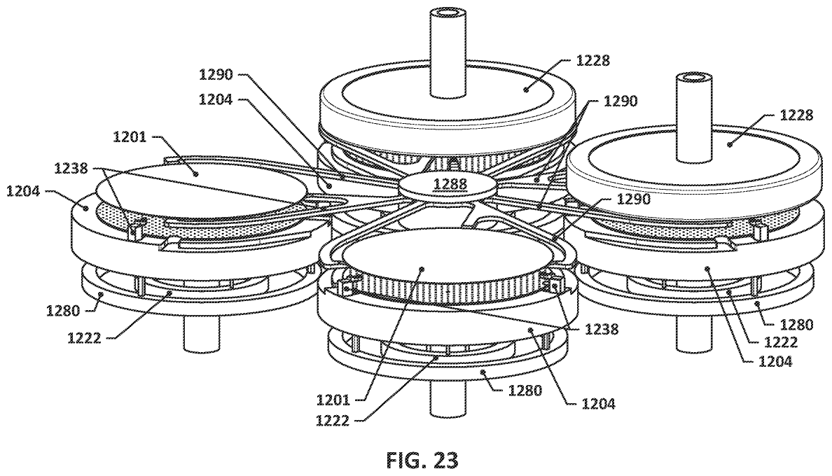

An indexer lift mechanism (not shown) may then be caused to move the forks 1290 vertically upward, as shown in FIG. 23. The forks 1290, which may normally rest within arcuate recesses in the exterior of the shower-pedestals 1204, may thus rise up and contact the edges of the wafers 1201 with their respective wafer lift surfaces 1294, as shown in FIG. 23. The continued upward movement of the forks 1290 may then cause the wafers 1201 to be lifted off their corresponding wafer support structures 1238 such that the wafers 1201 are now completely supported by the forks 1290 and such that the forks 1290 and the wafers 1201 are not in danger of colliding with any structures when the rotational indexer 1288 is caused to rotate.

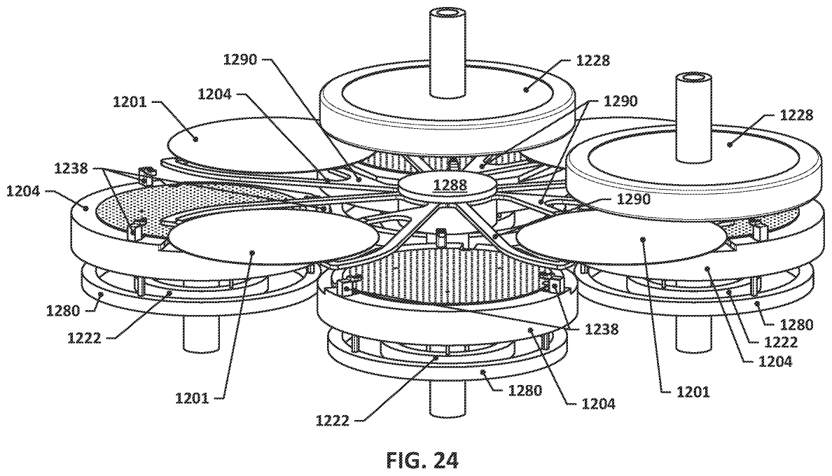

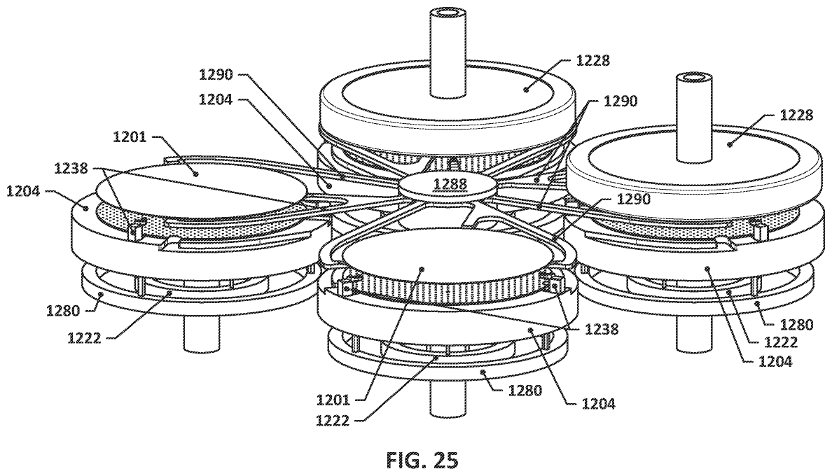

In FIG. 24, the rotational indexer 1288 has been controlled so as to rotate by 45°, thereby causing the forks 1290 and the wafers 1201 supported thereby to rotate halfway to the next station. In FIG. 25, the rotational indexer 1288 has completed its rotation and the wafers 1201 are now positioned directly over different shower-pedestals 1204 than they were positioned over immediately prior to such movement.

In FIG. 25, the rotational indexer 1288 has been controlled so as to move vertically downward, thereby causing the wafers 1201 to be placed on the wafer support structures 1238 of the shower-pedestals 1204 to which they have been transferred to. Subsequent or prior to such placement, the wafer-centering features may be caused to be extended, e.g., as depicted in FIG. 19′, so as to center the wafers 1201 with respect to the first reference axes of the station to which each has been transferred to.

As can be seen in FIGS. 14 through 25, all three systems that support the wafers 1201 during placement/retrieval from the tool, processing within the tool, and inter-station transfer within the tool are designed to contact the wafers 1201 only via edge contact. This reduces or eliminates the potential risk of particular generation, as well as reducing or eliminating any “shadowing” effect that may occur near the wafer edge during processing operations (or subsequent potential damage that may occur through contact between recently processed surfaces of the wafers 1201 and features that would otherwise contact the underside of the wafer at non-edge locations).

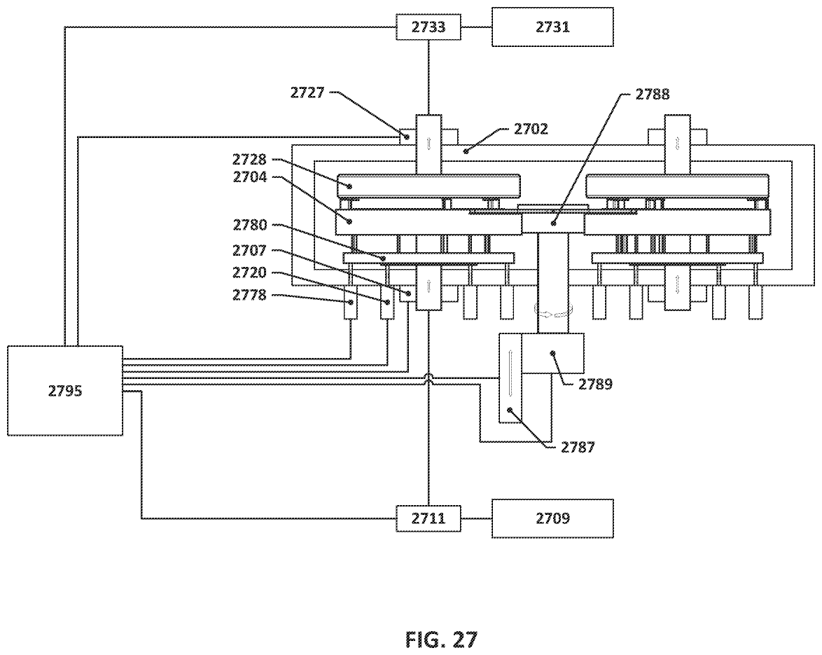

FIG. 27 depicts a simplified schematic view of a semiconductor processing tool having mechanisms and systems such as are discussed above. As shown, a chamber 2702 includes a plurality shower-pedestals 2704 and showerheads 2728 (examples of which are called out on one side but not the other—it will be understood that the depicted implementation is symmetric left-to-right with respect to the depicted components).

The chamber 2702 also includes a rotational indexer 2788; the rotational indexer 2788 may be supported by a rotational drive 2789 (e.g., an electric motor) that may, in turn, be supported by a vertically oriented linear drive system 2787. The linear drive system 2787 may be configured to translate the rotational drive 2789 up or down, and the rotational drive to rotate clockwise or counterclockwise, responsive to inputs received from a controller 2795. The controller 2795 may also be operatively connected with, e.g., connected directly or indirectly so as to be able to control, vertical lift mechanisms 2778, e.g., linear actuators, screw drives, pneumatic actuators, etc., and lift pin actuators 2720, e.g., linear actuators, screw drives, pneumatic actuators, etc. The vertical lift mechanisms 2778 may be configured to raise or lower, responsive to signals received from controller 2795, a wheel riser support structure 2780 (and wafer-centering features supported thereby), while the lift pin actuators 2720 may be configured to raise or lower lift pin support structure 2722 (and lift pins supported thereby) responsive to signals received from the controller 2795.

Also shown in FIG. 27 are showerhead vertical drive 2727 and shower-pedestal vertical drive 2707, each of which may be respectively operatively connected with controller 2795 such that the controller 2795 may cause either or both of the showerhead vertical drive 2727 and the shower-pedestal vertical drive 2707 to actuate up and/or down, thereby adjusting the spacing between the shower-pedestal 2704 and the showerhead 2728 responsive to signals received from the controller 2795. In some implementations, one of the showerhead vertical drive 2727 and the shower-pedestal vertical drive 2707 may be omitted, with the other being retained in order to still allow for adjustment of the showerhead 2728/shower-pedestal 2704 spacing.

The controller 2795 may also be operatively connected with one or more first valves 2711 and one or more second valves 2733. The one or more first valves 2711 may be fluidically connected with one or more first gas sources 2709 and the first plenum of the shower-pedestal 2704. The controller 2795 may be configured to control the one or more first valves 2711, e.g., by providing related control signals thereto, in order to cause one or more first processing gases to be delivered from the one or more first gas sources 2709 to the shower-pedestal 2704.

Similarly, the one or more second valves 2733 may be fluidically connected with one or more second gas sources 2731 and the second plenum of the showerhead 2728. The controller 2795 may be configured to control the one or more second valves 2733, e.g., by providing related control signals thereto, in order to cause one or more second processing gases to be delivered from the one or more second gas sources 2731 to the showerhead 2728.

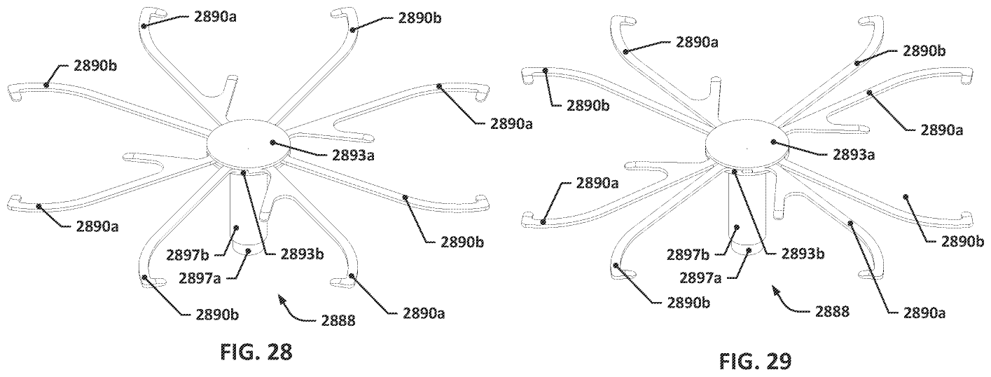

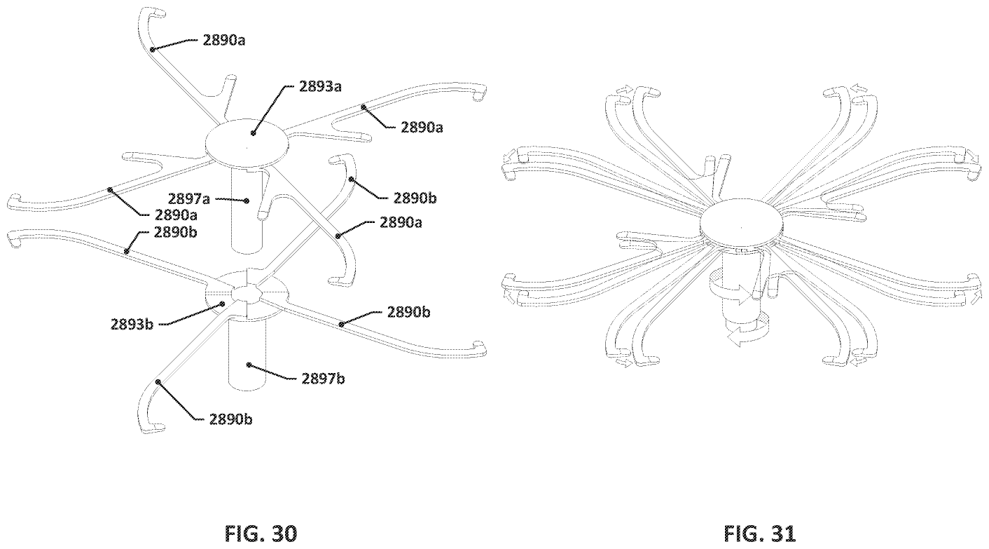

In some implementations, a rotational indexer may be used in such tools that has forks that may be transitioned between an open state and a closed state. FIGS. 28-31 depict representations of an indexer with openable/closable forks. FIG. 28 shows an indexer 2888 in a closed state, while FIG. 29 shows the same indexer 2888 in an open state. FIG. 30 shows the indexer 2888 in an exploded view, and FIG. 31 shows the indexer 2888 in both the open and closed states (with the open state shown in dashed lines).

As can be seen in FIGS. 28-31, the indexer 2888 may include forks that are split between first and second halves, e.g., first halves 2890a and second halves 2890b. Each pair of first and second halves 2890a and 2890b may, together, provide a fork structure that is configured to support a semiconductor wafer when the rotational indexer 2888 is in the closed state. The first halves 2890a may be mounted to, or an integral part of, a first hub 2893a, while the second halves 2890b may be mounted to, or an integral part of, a second hub 2893b. The first hub 2893a may be connected with a first shaft 2897a while the second hub 2893b may be connected with a second shaft 2897b. The second shaft 2897b may be hollow such that the first shaft 2897a may pass through it, allowing the first shaft 2897a and the second shaft 2897b to be coaxially arranged and each independently driven, for example, by two motors (not shown) with coaxial outputs or other mechanism allowing each shaft 2897a and 2897b to be independently driven.

The first halves 2890a, the first hub 2893a, and the first shaft 2897a may all be configured to rotate as a unit responsive to rotation of the first shaft 2897a. Similarly, the second halves 2890b, the second hub 2893b, and the second shaft 2897b may all be configured to rotate as a unit responsive to rotation of the second shaft 2897b. When the first shaft 2897a and the second shaft 2897b are both rotated in the same direction and at the same rate, the rotational indexer 2888 will rotate without any change in position between the first halves 2890a and the second halves 2890b. However, if the first shaft 2897a and the second shaft 2897b rotate in opposite directions or potentially in the same direction at different rates, the rotational position of the first hub 2893a relative to the second hub 2893b, and thus the rotational positions of the first halves 2890a relative to the second halves 2890b, may be caused to change. This allows the first halves 2890a and the second halves 2890b to be transitioned between an open state (shown in FIG. 29) and a closed state (shown in FIG. 28). In FIG. 31, arrows indicate contrarotation between the first shaft 2897a and the second shaft 2897b that results in the first halves 2890a and the second halves 2890b transitioning from the open state to the closed state. The opposite amount of contrarotation would, of course, cause the reverse transition.

The rotational indexer shown in FIGS. 28-31 may, as noted earlier, be used in, for example, any of the implementations discussed herein, e.g., in place of the rotational indexer 2788 or rotational indexer 1288, for example. The rotational indexer 2888 may, in the open state, allow for a greater separation between a wafer and pedestal and the first halves 2890a and the second halves 2890b than is permitted by fixed forks. This may allow for the forks (the first halves 2890a and the second halves 2890b) to be positioned further from the wafers and the pedestals supporting them during processing, thereby reducing the potential that the first halves 2890a and the second halves 2890b will interfere with processing of the wafer.

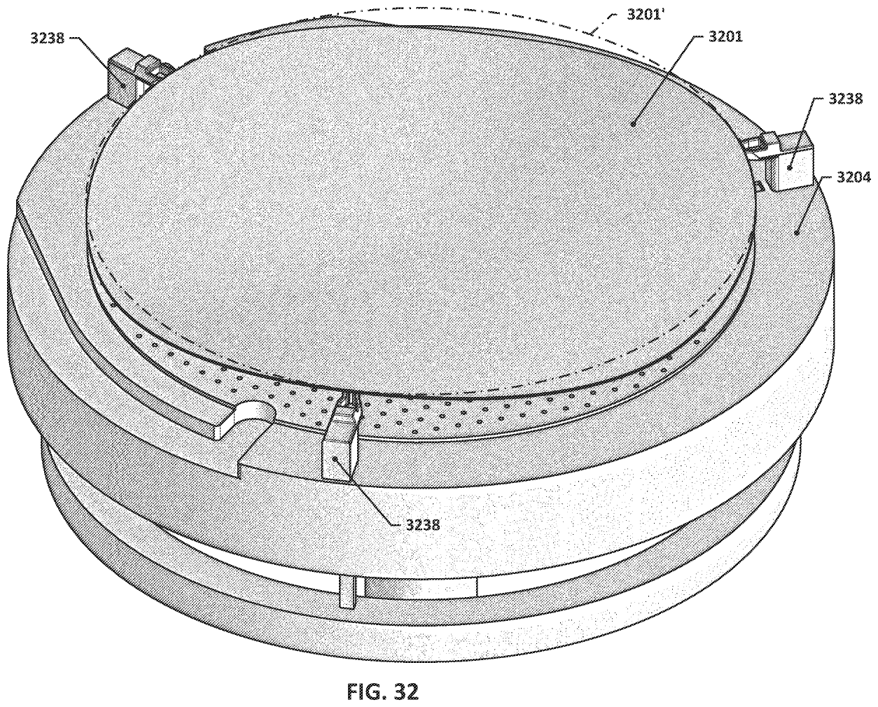

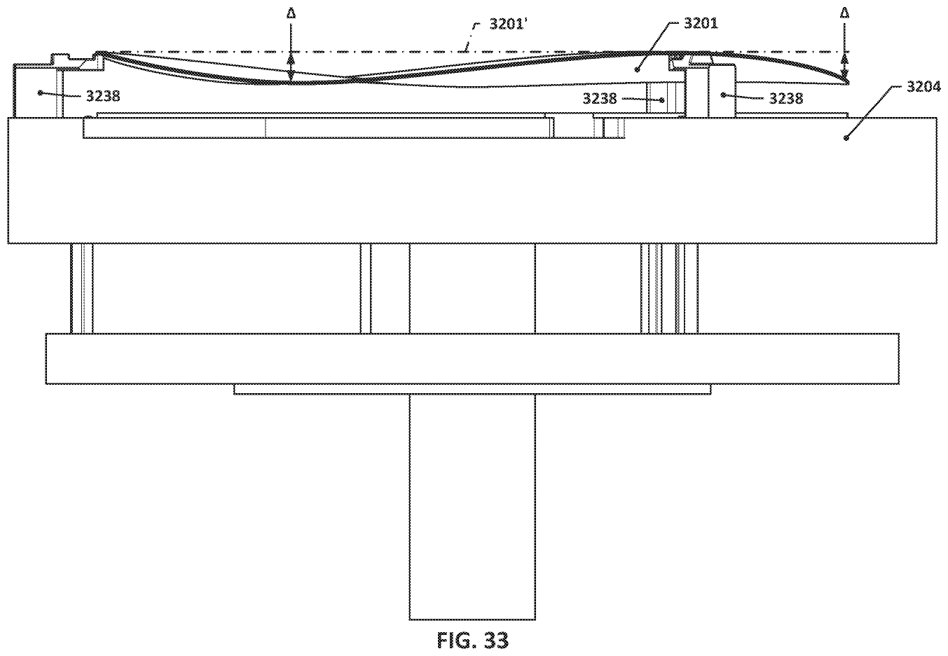

One issue that may arise in systems that may support a wafer such that the wafer is suspended above a shower-pedestal is that the wafer may, under its own weight, sag slightly. FIG. 32 depicts an example of such wafer sag, although exaggerated to a great degree. As shown in FIG. 32, a wafer 3201 is supported over a shower-pedestal 3204. FIG. 33 depicts a side view of the shower-pedestal and wafer of FIG. 32. The wafer 3201 is supported through contact between the wafer's outer edge and a plurality, e.g., three, wafer support structures 3238. The dashed circle 3201′ represents a planar circle that is the same size as the wafer 3201, e.g., where the wafer 3201 would be if the wafer 3201 were infinitely stiff and not subject to any sagging. As can be seen, the wafer 3201 is coincident with the planar circle 3201′ where the wafer 3201 is supported by each of the three wafer support structures 3238, but then droops or sags in between each pair of wafer support structures 3238 by amount Δ, as shown in FIG. 33. As noted above, the depicted sagging is extremely exaggerated in these Figures (and other Figures discussed below); this was done to make the sag easily discernible. However, it will be understood that in actual practice, the amount of sag Δ that is present may be on the order of only tens to hundreds of microns (for a 300 mm diameter wafer) and may not be readily perceptible to the human eye.

As discussed earlier, a ring-like structure, such as the focus ring 870, may be centered on, and placed over, the wafer 3201. Such a ring-like structure may, for example, overlap the outer circumference of the wafer 3201 by a small amount. The ring-like structure may act as a diffusion barrier that prevents process gases introduced to the underside of the wafer 3201 from diffusing up past the edge of the wafer 3201 and into the region in between the wafer 3201 and a showerhead (not shown, but see earlier Figures and discussion) into which a purge gas may be flowed. The ring-like structure may either contact the wafer 3201 about its outer edge or be positioned such that a small, e.g., on the order of low tens of microns or less, gap exists between the wafer outer edge and the ring structure outer edge. Such contact or such a small gap may, in combination with the flow of purge gas, prevent diffusion of process gas from the underside of the wafer 3201, through the interface between the wafer 3201 and the ring structure, and to the top surface of the wafer 3201. In effect, the ring structure acts to “extend” the outer edge of the wafer to a larger diameter such that the process gas that does manage to diffuse past the “extended” outer edge contacts the outer edge of the ring structure as opposed to the outer edge of the wafer 3201.

However, when the wafer 3201 exhibits sag, such as shown in FIG. 32, the distance between the ring structure and the wafer 3201 will vary if the ring structure is generally axially symmetric. As a result, any gap between the ring structure and the wafer 3201 will be caused to vary about the circumference of the wafer 3201 (or a gap may be caused to come into existence at various locations about the circumference of the wafer). Such gaps may be large enough that process gas that would normally be prevented from flowing through the wafer/ring structure interface is able to diffuse through that interface and reach the outer edge of the wafer 3201, thereby contaminating it/subjecting it to undesired deposition or etching.

In order to mitigate or eliminate this potential diffusion of process gas through the ring structure/wafer interface, the ring structure may have a design that eschews the traditional design of such ring structures in which the surface of the ring structure that contacts the wafer or is closest to the wafer is made to be axially symmetric, e.g., planar. Instead, such a surface may be made to have a varying circumferential profile that varies in a manner similar to the expected variation in a similar circumferential profile of the wafer (when supported through contact on the wafer edge similar to as shown in FIG. 32).

A “circumferential profile” refers to a profile that is taken about the circumference of an object. For example, if one were to take the surface of a ring structure and intersect it with a cylindrical surface (not an actual object, but an abstract surface) that was centered on the center axis of the ring structure, the curve formed by the intersection of the ring structure surface and the cylindrical surface would be the “circumferential profile” of that ring structure surface. Put another way, a circumferential profile is similar to a cross-sectional profile, but evaluated about the circumference of a cylindrical surface instead of across a planar surface (as would be the case in a traditional cross-section view).

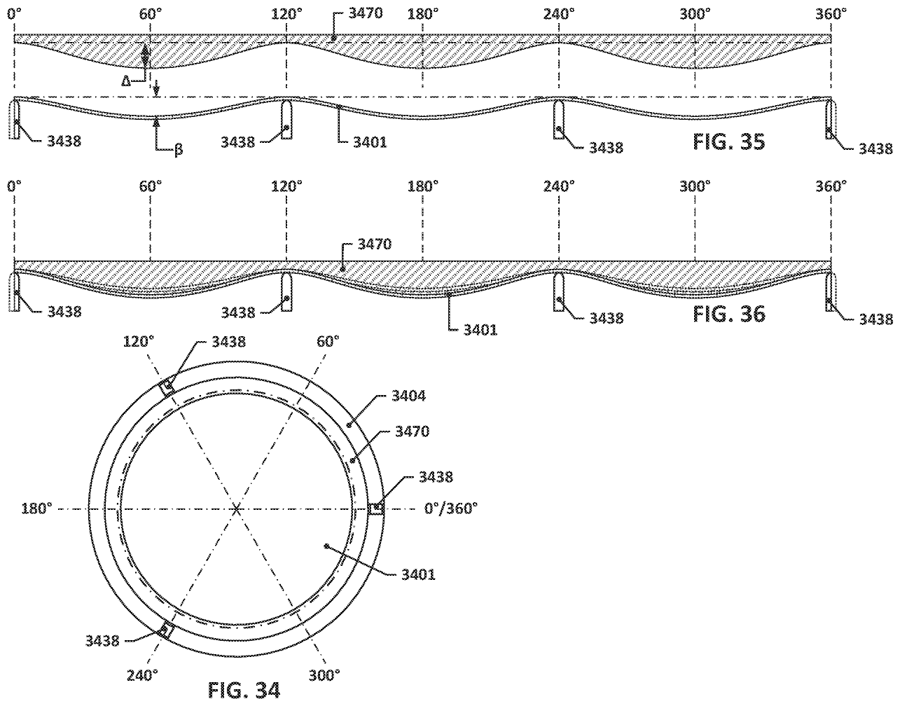

FIG. 34 shows a top view of a ring structure 3470 that rests on top of a wafer 3401 that is supported by wafer support structures 3438 of shower-pedestal 3404. FIGS. 35 and 36 depict the circumferential profile of the wafer 3401 and the ring structure 3470 in two different states (with the ring structure 3470 lifted off of the wafer 3401 in FIG. 35, and with the ring structure 3470 resting on the wafer 3401 in FIG. 36). The circumferential profiles in FIGS. 35 and 36 were taken along the dash-dot-dash circle of radius R in FIG. 34 and then “unrolled” to be in a flat, two-dimensional state to make it easier to visualize. The distance R in this case was selected to be a value in between the inner radius of the ring structure 3470 and the radius of the outer edge of the wafer 3401. More specifically, the distance R in this example was selected to be the same distance as the distance from the center axis to the point of contact between the ring structure 3470 and the wafer 3401.

FIGS. 34 through 36 also show markings for various angular positions about the ring structure. As can be seen in FIG. 35, the circumferential profile of the wafer 3401 exhibits a periodicity to it that correlates with the angular spacing between the wafer support structures 3438. At each wafer support structure 3438, the circumferential profile of the wafer 3401 is at a maximum elevation, and midway between each pair of adjacent support structures the circumferential profile of the wafer 3401 is at a minimum elevation. The difference between the maximum elevation and the minimum elevation is represented by distance β in FIG. 35.

Also visible in FIG. 35 is the circumferential profile of the ring structure 3470. The ring structure 3470 has a bottom surface that exhibits a varying circumferential profile that generally matches that of the wafer 3401. For example, if a reference plane is defined as being coincident with a top surface of the ring structure 3470 and perpendicular to a center axis of the ring structure (and/or the center axis of the circumferential profile), the bottom surface of the ring structure may vary such that a normal distance from the reference plane to the bottom surface at radial distance R from the center axis varies between at least a first value and a second value. The first value and the second value may generally be understood to represent the maximum and minimum distances of the circumferential profile from the reference plane. Generally speaking, the transition of the circumferential profile from the first value to the second value (and vice versa) may occur in a smooth manner, e.g., so as to avoid step transitions, in order to mimic the gradual changes in the amount of wafer sag that occur about the circumferences of the wafers.

In many cases, such variation may be periodic, e.g., recurring in a generally cyclical manner at regular intervals, e.g., every 120°. However, such variations may also repeat but also be non-periodic, e.g., at 0°, 100°, and 240° angular locations about the center axis of the ring structure. In many cases, there will be three repetitions of each such variation, e.g., to match the areas in which a wafer supported at three points will sag. However, it will be understood that while the examples herein focus on variants having three repetitions of such variations to match a wafer that is supported at three points along its edge, other implementations may have a larger number of variations to match circumferential profiles of wafers supported at more than three points along their edges. For example, in some implementations, wafers may be supported at more than three points along their edges. In some such implementations, wafers may be supported at 4, 5, 6, 7, 8, 9, 10, 11, 12, 13, 14, 15, 16, 17, 18, 19, 20, 21, 22, 23, 24, 25, 26, 27, 28, 29, or 30 points along their edges, and the circumferential profiles of ring structures designed to be used with wafers supported in such a manner may correspondingly have between 4 and 30, as appropriate, low points and high points, e.g., similar to the example above.

When the ring structure 3470 is placed on top of the wafer 3401, the two circumferential profiles may generally align and the distance between the ring structure and the wafer along the radius of the circumferential profile may be maintained within a desired threshold, e.g., within a distance small enough to block potential process gas diffusion through that interface.

In some implementations, the circumferential profile of the ring structure 3470 may be defined such that the absolute value of the difference between the first value and the second value is greater than 40 microns and less than or equal to 400 microns, thereby potentially being able to compensate for between approximately 40 microns and 400 microns of wafer edge sag. In some such implementations, the absolute value of the difference between the first value and the second value may be greater than or equal to 50 microns and less than or equal to 150 microns, greater than or equal to 100 microns and less than or equal to 200 microns, greater than or equal to 250 microns and less than or equal to 350 microns, or greater than or equal to 300 microns and less than or equal to 400 microns.

In some instances, the circumferential profile of the ring structure 3470 may be designed such that the absolute value of the difference between the first value and the second value is actually greater, by some small amount (e.g., on the order of low tens of microns) than the maximum expected amount of wafer edge sag in the wafers that the ring structure 3470 is to be used with. For example, the absolute value of the difference between the first value and the second value for the ring structure 3470 may be caused to be larger by a third value than the expected maximum amount of wafer edge sag in the wafers that the ring structure is designed to be used with. The third value may, in some cases, be greater than zero microns and less than or equal to 50 microns, e.g., between zero and 40 microns, between zero and 30 microns, between zero and 20 microns, etc.

In such implementations, the third value may be selected so as to ensure that there is always contact between the wafer 3401 and the bottom surface of the ring structure 3470 even if there is some variation in the maximum amount of edge sag that the wafer 3401 exhibits. For example, the amount of edge sag that wafers exhibit may vary slightly from wafer to wafer depending on, for example, temperature, wafer crystal orientation, potential localized effects due to features patterned onto the wafer, thickness variation in the wafer, etc. The maximum amount of wafer sag may, for example, be an average expected maximum amount of wafer sag, and there may be potential additional wafer sag beyond that in some cases. If the absolute value of the difference between the first value and the second value for the ring structure 3470 is selected to be larger than the expected amount of wafer edge sag by the third value, then this will have the effect of causing the ring structure 3470 to come to rest on the lowest parts of the wafer edge, i.e., the portions of the wafer edge that have sagged the most. At this point, the points of the ring structure that are located over the wafer support structures 3438 may not be in contact with the wafer 3401. However, the weight of the ring structure 3470 may push down on the edge of the wafer 3401, thereby causing the wafer 3401 to sag further until the ring structure is resting directly on top of the portions of the wafer 3401 that are supported by the wafer support structures 3438, thereby causing the wafer edge to come into contact with the ring structure around its full circumference. This is illustrated in FIG. 36, in which the ring structure 3470 has, through its own weight, been caused to deflect the wafer 3401 such that the ring structure 3470 comes into contact with the wafer 3401 along its entire circumference. The circumferential profile of the wafer 3401 prior to such additional deflection is represented in FIG. 36 by the dotted outline of the wafer 3401, while the solid outline of the wafer 3401 represents the wafer in its further-deflected state.

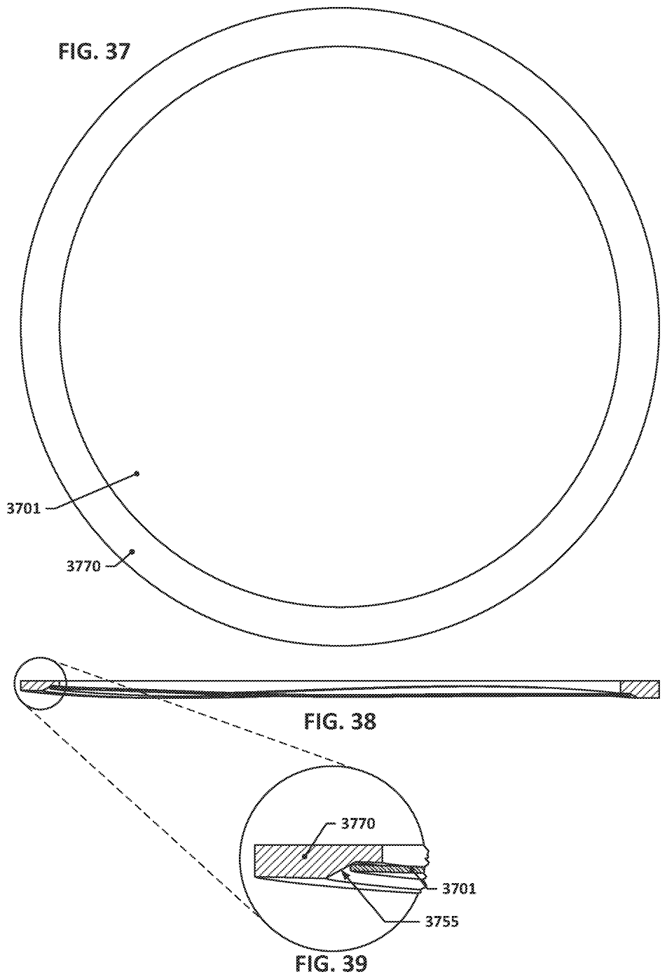

FIG. 37 depicts a top view of a ring structure 3770 and a wafer 3701 that may be used in some implementations. FIG. 38 depicts a section view of FIG. 37, and FIG. 39 depicts a detail view of the circled region in FIG. 38. As can be seen in the detail view of FIG. 39, the ring structure 3770 overlaps the edge of the wafer 3701 by a small amount—however, the overlapping area does not actually touch the top surface of the wafer 3701. The ring structure instead has a bottom surface that has a portion 3755 that is at an oblique angle with respect to a center axis of the ring structure 3770—this oblique aspect to the portion 3755 of the bottom surface of the ring structure 3770 may extend entirely around the ring structure 3770, thereby producing, in conjunction with the above-mentioned circumferential variances, a wavy conical frustum surface. This surface, due to being inclined at an oblique angle from the center axis (as opposed to being perpendicular to the center axis), may rest on the outer edge of the wafer 3701, thereby producing edge contact on an outermost edge of the wafer bevel (as opposed to contacting the upper surface of the wafer 3701).

The ring structures discussed herein may be made from a variety of materials, although such materials may be selected to be resistant or non-reactive to the process chemicals that may be provided to the underside of the wafers being processed. For example, such ring structures may be made of a ceramic material, such as alumina (aluminum oxide), and then machined or ground to achieve the desired circumferentially varying profile.

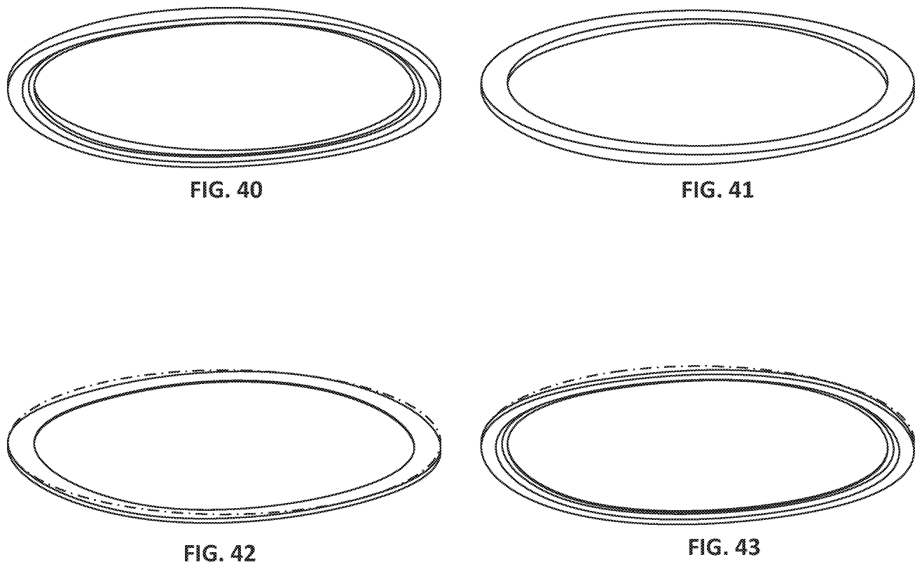

The top surface of such ring structures may, in some cases, be planar or axially symmetric, as shown in FIGS. 40 and 41 (top and bottom dimetric views, respectively), thereby allowing them to be made nominally parallel to the underside of the showerhead that may be positioned immediately thereabove and allowing for a constant gap distance between the showerhead and the ring structure to be maintained. In other cases, as shown in FIGS. 42 and 43, the top surface of the ring structure may be formed so as to have a varying circumferential profile as well, e.g., one that generally follows that of the bottom surface of the ring structure. In FIGS. 42 and 43 (top and bottom dimetric views, respectively), the dash-dot-dash lines represent the outer edge of the top surface as it would be if the top surface were planar, e.g., as shown in FIGS. 40 and 41. In actual practice, such non-axially symmetric top surfaces would typically only vary on the order of tens to hundreds of microns, so the overall variation in height of the top surface would likely only be on the order of a millimeter or less, which may still provide adequate gap control between the showerhead and the ring structure (as purge gas is provided to the gap between the showerhead and the ring structure, gas flow uniformity is not as consequential as it might be if process gases were being flowed out of the showerhead—the main concern would be maintaining a small enough gap, e.g., one the order of a couple of millimeters, to avoid potential plasma generation within the gap).

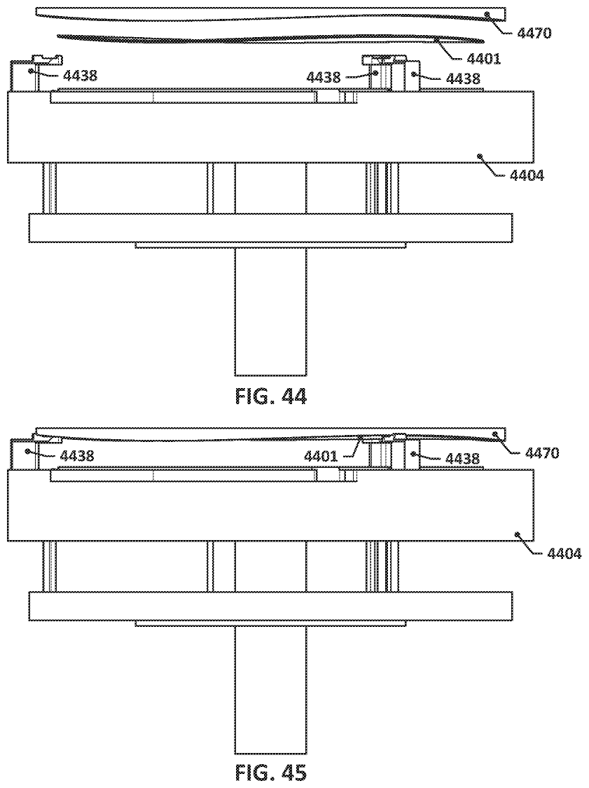

FIGS. 44 and 45 depict exploded and non-exploded side views of a wafer 4401 that rests on wafer supports 4438 of a shower-pedestal 4404 and has a ring structure 4470 placed thereover. As can be seen, the ring structure 4470 aligns with the sagging areas of the wafer (the sag is, again, exaggerated) to avoid the creation of gaps (or larger gaps) in the sagging areas of the wafer.

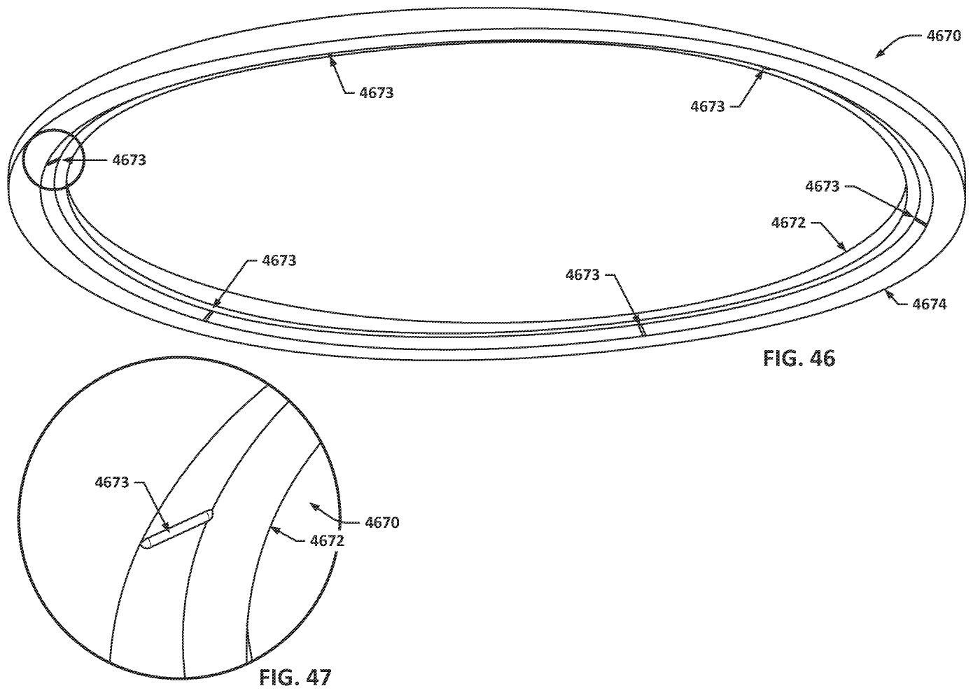

In some implementations, the ring structure may have a plurality of protrusions on its bottom surface, e.g., a circular array of protrusions, that may be positioned so as to lie along a contoured or non-axially symmetric portion of the bottom surface. FIG. 46 depicts an isometric bottom view of an example ring structure 4670 having six protrusions 4673 located on the bottom surface of the ring structure 4670 in between an inner edge 4672 and an outer edge 4674 thereof. The protrusions 4673 may be positioned at equally spaced locations about the circumference of the ring structure 4670. The protrusions 4673 may be used as minimum contact area (MCA) features that may contact the edge of a wafer with a minimum (or practical minimum) of surface area contact. For example, the protrusions may be semi-cylindrical ridges that extend along the bottom surface along axes that are coplanar with planes that are coplanar with a center axis of the ring structure, e.g., radiating generally outward (and along the bottom surface). This is shown more clearly in FIG. 47, which depicts a detail view of a portion of the ring structure 4670. In the depicted example, the protrusions 4673 lie on a generally conical portion of the bottom surface of the ring structure (this surface, however, may not be truly conical, as discussed earlier—it may be contoured so as to have a circumferential profile that varies periodically, per the examples discussed above). Accordingly, when the ring structure 4670 is placed on top of a wafer so as to contact the edge of the wafer with its bottom surface, the contact between the wafer and the ring structure 4670 may be limited to the protrusions 4673. This may reduce the contact area between the wafer and the ring structure 4670, thereby reducing the potential for particulate generation due to abrasion between the wafer and the ring structure 4670.

In some additional or alternative implementations, ring structures such as the above-discussed ring structures, or the focus rings discussed earlier, may be provided as multi-piece assemblies. For example, a ring structure may have an inner portion and an outer portion that encircles the inner portion. The outer portion may be configured such that the inner portion may rest on, and be supported by, the outer portion but may also be lifted vertically upward off of the inner portion when subjected to a force from below. Such implementations may allow the weight of the ring structure to be split between the inner portion and the outer portion thereof. When the ring structure is then brought into contact with a wafer positioned underneath it, the wafer may lift the inner portion clear of the outer portion and support it. The wafer may thus bear the weight of the inner portion but does not need to bear the weight of the outer portion.

FIG. 48 depicts an isometric sectional view of an example showerhead 4828 and shower-pedestal 4804 supporting a wafer 4801. FIGS. 49 through 51 depict detail views of the circled portion of FIG. 48 during various positions of a focus ring 4870, e.g., a ring structure.

As shown in FIG. 49, the focus ring 4870 has an inner portion 4870a and an outer portion 4870b. The inner portion 4870a may have an inner edge that has a smaller diameter than an outer diameter of the wafer 4801 and an outer edge that has a larger diameter than an inner diameter of the outer portion 4870b. For example, the outer portion 4870b may have a stepped-down region along the inner edge that may act to receive the outer edge of the inner portion 4870a. The outer edge of the outer portion 4870b may have a diameter that is larger than a diameter of an inner edge of a ring support collar 4871, thereby allowing the outer portion 4870b to rest on and be supported by the ring support collar 4871.

In FIG. 49, the focus ring 4870 is entirely supported by the ring support collar 4871, as the showerhead 4828 is at an elevated position relative to the shower-pedestal 4804.

In FIG. 50, the showerhead 4828 and the shower-pedestal 4804 have been moved into a relative position where the focus ring 4870 is just contacting wafer support structures 4838 and/or resting on the outer edge of the wafer 4801. In this position, the inner portion 4870a may also still be partially supported by the outer portion 4870b.

In FIG. 51, the showerhead 4828 and the shower-pedestal 4804 have been moved into a relative position where the inner portion 4870a of the focus ring 4870 is resting on the wafer support structures 4838 and/or the outer edge of the wafer 4801, and the outer portion 4870b of the focus ring 4870 is resting on the ring support collar 4871, resulting in a small vertical gap between the inner portion 4870a and the outer portion 4870b. It will be appreciated that the gap may be smaller than that shown, e.g., such that it is difficult for gases to flow through the interface between the inner portion 4870a and the outer portion 4870b.

Such arrangements allow the size of the focus ring 4870 to be increased beyond the size of the inner portion 4870a without increasing the weight that bears on the wafer 4801 when the focus ring 4870 is placed on the wafer 4801. This allows the focus ring 4870 weight that is placed on the wafer 4801 to be at least somewhat decoupled from the size of the focus ring 4870, as well as the size of the showerhead 4828 that may support the focus ring 4870.

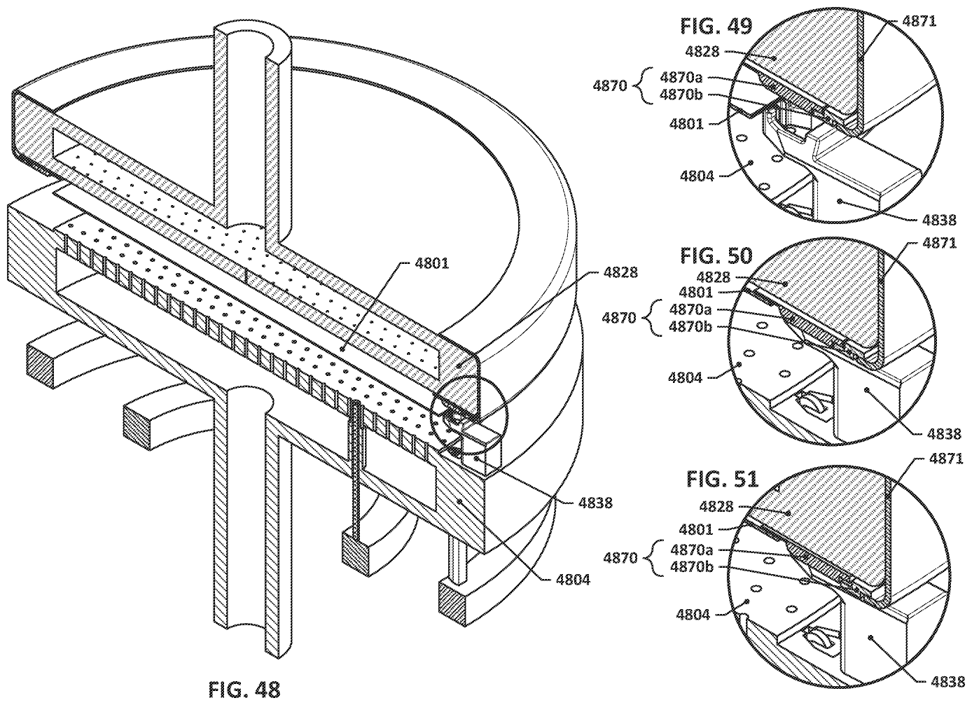

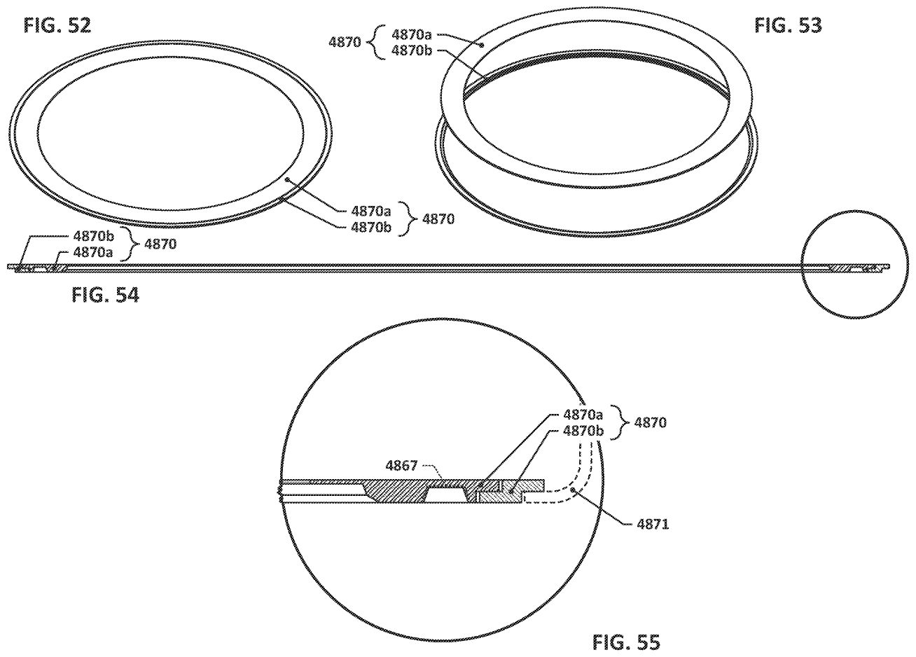

FIGS. 52 through 55 depict various views of the focus ring 4870. FIG. 52 is an isometric view of the focus ring 4870 when the inner portion 4870a is resting on, and supported by, the outer portion 4870b. FIG. 53 is an isometric view of the focus ring 4870 with the inner portion 4870a lifted clear of the outer portion 4870b. FIG. 54 is a cross-sectional view of the focus ring 4870, and FIG. 55 is a detail view of the circled portion of FIG. 54. As can be seen in FIG. 55, the inner portion 4870a of the focus ring 4870 may be equipped with pockets or recesses 4867 that may, for example, engage with the wafer support structures of a shower-pedestal, as discussed earlier with respect to FIG. 10. The inner portion 4870a and the outer portion 4870b may, in most cases, be generally axially symmetric (aside from features such as the pockets or recesses 4867 or protrusions 4873, if present).

It will be appreciated that the circumferentially varying ring structures discussed herein may be used in any semiconductor processing systems in which a wafer is supported at discrete locations along its edge with the center of the wafer generally unsupported, thereby resulting in wafer edge sag. Such structures are not limited to use with the specific systems shown herein.

The control of a wafer back-side processing system, as well as potentially other equipment discussed above (such as wafer handling robots, indexers, etc.) may be facilitated through the use of a controller that may be included as part of a semiconductor processing tool, including, for example, the above-described example semiconductor processing tools and/or chambers. The systems discussed above may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), valve operation, light source control for radiative heating, pressure settings, vacuum settings, power settings, radio frequency (RF) generator settings, RF matching circuit settings, frequency settings, flow rate settings, fluid delivery settings, positional and operational settings, wafer transfers into and out of a tool or chamber and other transfer tools and/or load locks connected to or interfaced with a specific system. More specifically, such a controller may be configured to control, among other systems, the various actuators and motors of a back-side wafer processing system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon oxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

As discussed above, the apparatuses and systems discussed herein may be used to perform processing on at least the underside of a wafer. Such processing may be particularly useful in the context of wafers having large numbers of feature layers, e.g., 3D memory structures or logic devices. Such wafers may, due to the number of feature layers present, warp or bow due to the compressive or tensile forces that may develop within each such feature layer. Systems that are able to perform processing operations on the underside of such wafers, i.e., on a side of the wafer opposite the side on which such feature layers exist, may able to apply material films to such wafers that may generate countervailing tensile or compressive forces that may cancel out or mitigate the stress imbalance through the thickness of the wafer, thereby causing the wafer to bow or warp less.

Traditional dual-electrode radio-frequency plasma-enhanced chemical vapor deposition (PECVD) or etch systems have one gas-flowing electrode that is used for radio-frequency power supply or for ground in the generation of a plasma. Typically, the gas-flowing electrode (also referred to as a showerhead) is on the top side of the reactor, causing the reactants to flow onto the top side of the wafer, thereby causing processing to occur only on the top side of the wafer.

In the systems discussed herein, dual gas-flowing electrodes are provided—one by way of the showerhead and the other by way of the shower-pedestal. Either of the electrodes may serve as an RF electrode to provide AC power for enabling a plasma for use in film deposition or etch processes. This dual gas-flowing electrode system is capable of selectively depositing or etching films on both sides or only one side of the wafer.

In one implementation, the back-side gas flow provided by the shower-pedestal enables the wafer processing operations to be performed on the back-side of the wafer while the front-side gas flow from the showerhead can deposit on the front side of the wafer. In other implementations (on separate tools, or even the same tool or even the same station within the same tool), the system can be set up to selectively process only one side of the wafer by turning on and off the reactants that cause the processing to occur on a particular side of the wafer and replacing them with non-reacting gases (e.g., inert gases).

The shower-pedestals and/or showerheads discussed herein may, in some implementations, include an active heater to get the process gases flowed therethrough to a desired temperature prior to delivery into the chamber housing the shower-pedestals and/or showerheads.

Broadly speaking, when used for deposition-based processing, the use of shower-pedestal may provide several advantages for combating stress and bowing issues by depositing a film on the back side of the wafer. The back-side film may counteract the stress that arises from the front-side deposition, thereby causing a neutral stress condition (or substantially neutral stress, e.g., less than about +/−150 MPa) to develop, thereby resulting in a wafer that shows no bowing (or substantially no bowing, e.g., less than about 150 μm of bow). If the film deposited on the front side is a tensile film, then the back-side film should also be tensile to balance out the overall stress. Likewise, if the front-side film is compressive, then the back-side film should also be compressive. The back-side film may be deposited through various reaction mechanisms (e.g., chemical vapor deposition (CVD), plasma enhanced chemical vapor deposition (PECVD), atomic layer deposition (ALD), plasma enhanced atomic layer deposition (PEALD), low pressure chemical vapor deposition (LPCVD), etc)—thus, the equipment discussed herein may be generally usable or adaptable for performing any such types of processing. In some implementations, plasma-enhanced chemical vapor deposition may be used due to the high deposition rate achieved in this type of reaction.

For deposition operations, certain deposition parameters may be tuned to produce a back-side film having a desired stress level. One of these deposition parameters is the thickness of the deposited back-side film. Thicker films may induce more stress in the wafer, while thinner films (of the same composition and deposited under the same conditions) may induce less stress in the wafer. Therefore, in order to minimize the amount of material consumed in forming the back-side layer, the layer may be deposited relatively thinly under conditions that promote formation of a highly stressed film.

As mentioned, stacks of deposited materials on the front-side of the wafer, e.g., to make memory or logic circuits are more likely to result in wafer stress and bowing. One example stack that may cause these problems is a stack having alternating layers of oxide and nitride (e.g., silicon oxide/silicon nitride/silicon oxide/silicon nitride, etc.). Another example stack likely to result in bowing includes alternating layers of oxide and polysilicon (e.g., silicon oxide/polysilicon/silicon oxide/polysilicon, etc.). Other examples of stack materials that may be problematic include, but are not limited to, tungsten and titanium nitride. The materials in the stacks may be deposited through chemical vapor deposition techniques such as plasma-enhanced chemical vapor deposition (PECVD), low-pressure chemical vapor deposition (LPCVD), metal organic chemical vapor deposition (MOCVD), atomic layer deposition (ALD), plasma-enhanced atomic layer deposition (PEALD), or direct metal deposition (DMD), etc. These examples are not intended to be limiting. Certain disclosed implementations may be useful whenever wafer stress and/or bowing are induced due to material being present on the front side of the wafer.

The front-side stacks may be deposited to any number of layers and thicknesses. In a typical example, such a stack may include between about 32 to 72 layers and may have a total thickness between about 2 μm to 4 μm. The stress induced in the wafer by the stack may be between about−500 MPa to about +500 MPa, resulting in a bow that is frequently between about 200 μm to 400 μm (for a 300 mm wafer), and even greater in some cases.

The material deposited on the back-side of the wafer may be a dielectric material in various implementations. In some cases, an oxide and/or nitride (e.g., silicon oxide/silicon nitride) may be used. Examples of silicon-containing reactants that may be used to produce such a layer include, but are not limited to, silanes, halosilanes, and aminosilanes. A silane contains hydrogen and/or carbon groups but does not contain a halogen. Examples of silanes are silane (SiH4), disilane (Si2H6), and organo-silanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like. A halosilane contains at least one halogen group and may or may not contain hydrogens and/or carbon groups. Examples of halosilanes are iodosilanes, bromosilanes, chlorosilanes and fluorosilanes. Although halosilanes, particularly fluorosilanes, may form reactive halide species that can etch silicon materials, in certain implementations described herein, the silicon-containing reactant is not present when a plasma is struck. Specific chlorosilanes are tetrachlorosilane (SiCl4), trichlorosilane (HSiCl3), dichlorosilane (H2SiCl2), monochlorosilane (ClSiH3), chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like. An aminosilane includes at least one nitrogen atom bonded to a silicon atom, but may also contain hydrogens, oxygens, halogens and carbons. Examples of aminosilanes are mono-, di-, tri- and tetra-aminosilane (H3Si(NH2)4, H2Si(NH2)2, HSi(NH2)3 and Si(NH2)4, respectively), as well as substituted mono-, di-, tri- and tetra-aminosilanes, for example, t-butylaminosilane, methylaminosilane, tert-butylsilanamine, bis(tertiarybutylamino) silane (SiH2(NHC(CH3)3)2 (BTBAS), tert-butyl silylcarbamate, SiH(CH3)—(N(CH3)2)2, SiHCl—(N(CH3)2)2, (Si(CH3)2NH)3 and the like. A further example of an aminosilane is trisilylamine (N(SiH3)). Other potential silicon-containing reactants include tetraethyl orthosilicate (TEOS), and cyclic and non-cyclic TEOS variants such as tetramethoxysilane (TMOS), fluorotriethoxysilane (FTES), Trimethylsilane (TMS), octamethyltetracyclosiloxane (OMCTS), tetramethylcyclotetrasiloxane (TMCTSO), dimethyldimethoxysilane (DMDS), hexamethyldisilazane (HMDS), hexamethyldisiloxane (HMDSO), hexamethylcyclotrisiloxane (HMCTSO), dimethyldiethoxysilane (DMDEOS), methyltrimethoxysilane (MTMOS), tetramethyldisiloxane (TMDSO), divinyltetramethyldisiloxane (VSI2), methyltriethoxysilane (MTEOS), dimethyltetramethoxydisiloxane (DMTMODSO), ethyltriethoxysilane (ETEOS), ethyltrimethoxysilane (ETMOS), hexamethoxydisilane (HMODS), bis(triehtoxysilyl) ethane (BTEOSE), bis(trimethoxysilyl) ethane (BTMOSE), dimethylethoxysilane (DMEOS), tetraethoxydimethyldisiloxane (TEODMDSO), tetrakis (trimehtylsiloxy) silane (TTMSOS), tetramethyldiethoxydisiloxane (TMDEODSO), triethoxysilane (TIEOS), trimethoxysilane (TIMEOS), or tetrapropoxysilane (TPOS).

Example nitrogen-containing reactants that may be used to create such a layer include, but are not limited to, ammonia, hydrazine, amines (e.g., amines bearing carbon) such as methylamine, dimethylamine, ethylamine, isopropylamine, t-butylamine, di-t-butylamine, cyclopropylamine, sec-butylamine, cyclobutylamine, isoamylamine, 2-methylbutan-2-amine, trimethylamine, diisopropylamine, diethylisopropylamine, di-t-butylhydrazine, as well as aromatic containing amines such as anilines, pyridines, and benzylamines. Amines may be primary, secondary, tertiary, or quaternary (for example, tetraalkylammonium compounds). A nitrogen-containing reactant can contain heteroatoms other than nitrogen, for example, hydroxylamine, t-butyloxycarbonyl amine and N-t-butyl hydroxylamine are nitrogen-containing reactants.

Examples of oxygen-containing co-reactants that may be used to create such layers may include oxygen, ozone, nitrous oxide, carbon monoxide, nitric oxide, nitrogen dioxide, sulfur oxide, sulfur dioxide, oxygen-containing hydrocarbons (CxHyOz), water, mixtures thereof, etc.

The flow rate of these reactants may depend greatly on the type of reaction through which the back-side layer is deposited. Where CVD/PECVD are used to deposit the back-side layer, the flow rate of the silicon-containing reactant may be between about 0.5 ml/min to 10 mL/min (before atomization), for example between about 0.5 mL/min to 5 mL/min. The flow rate of a nitrogen-containing reactant, oxygen-containing reactant, or other co-reactant may be between about 3 SLM to 25 SLM, for example between about 3 SLM to 10 SLM.

In certain implementations, the back-side layer may be removed after further processing. Where this is the case, the composition of the back-side layer may be chosen such that it can be easily removed from the substrate at an appropriate time. In this regard, there may be a high selectivity between the material of the back-side layer (e.g., the dielectric) and the material of the underlying substrate (e.g., silicon) in the desired removal chemistry.

The optimal thickness of the back-side layer may depend on the amount of stress induced by the deposition on the front side of the wafer, as well as the conditions under which the back-side layer is deposited. The back-side layer may be deposited to a thickness at which the stress in the wafer becomes negligible (e.g., less than about 150 MPa). In these or other implementations, the back-side layer may be deposited to a thickness at which the wafer bow becomes negligible (e.g., less than about 150 μm of bow). In some cases, this corresponds to a back-side layer thickness between about 0.1 μm to 2 μm, for example between about 0.3 μm to 2 μm, or between about 0.1 μm to 1 μm, or between about 0.3 μm to 1 μm. Where silicon nitride is used to form the back-side layer, a film having a thickness of about 0.3 μm may be sufficient to mitigate a bow of about 50 μm to 200 μm. As mentioned above, a higher-stress back-side layer may be used to reduce the required thickness of the back-side layer needed to overcome a thicker, but lower-stress front-side layer. This may help conserve materials and reduce costs, e.g., by requiring less processing time. For more information regarding backside deposition techniques, reference may be made to U.S. Pat. No. 9,881,788, which is owned by the same assignee as the present application and is hereby incorporated herein by reference in its entirety.

The use, if any, of ordinal indicators, e.g., (a), (b), (c) . . . or (1), (2), (3) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

For the purposes of this disclosure, the term “fluidically connected” is used with respect to volumes, plenums, holes, etc., that may be connected with one another, either directly or via one or more intervening components or volumes, in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet. The term “fluidically adjacent,” if used, refers to placement of a fluidic element relative to another fluidic element such that there are no potential structures fluidically interposed between the two elements that might potentially interrupt fluid flow between the two fluidic elements. For example, in a flow path having a first valve, a second valve, and a third valve placed sequentially therealong, the first valve would be fluidically adjacent to the second valve, the second valve fluidically adjacent to both the first and third valves, and the third valve fluidically adjacent to the second valve.

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The term “operatively connected” is to be understood to refer to a state in which two components and/or systems are connected, either directly or indirectly, such that, for example, at least one component or system can control the other. For example, a controller may be described as being operatively connected with a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely cannot supply such power directly to the resistive heating unit due to the currents involved, but it will be understood that the controller is nonetheless operatively connected with the resistive heating unit.

It is understood that the examples and implementations described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure. However, the present disclosure is at least directed at, and inclusive of, the following non-exclusive list of numbered implementations:

Implementation 1: An apparatus including:
a shower-pedestal having a plurality of first gas distribution ports distributed across a first surface of the shower-pedestal, the first surface of the shower-pedestal defining a first average midplane;
a plurality of wafer support structures extending from the shower-pedestal and positioned about a first reference axis that intersects the first surface of the shower-pedestal and is perpendicular to the first average midplane, where:
   the plurality of wafer support structures are further positioned around a region that includes the first surface of the shower-pedestal,
   each wafer support structure has a corresponding wafer support surface that is non-parallel with respect to the first average midplane,
   each wafer support surface has a portion that is positioned at least a first distance away from the first average midplane in a direction perpendicular thereto and a second distance from the first reference axis in a direction perpendicular thereto.

Implementation 2: The apparatus of implementation 1, where at least a portion of each wafer support surface forms an angle of greater than zero degrees and equal to or less than 15 degrees with respect to the first average midplane.

Implementation 3: The apparatus of either of implementations 1 or 2, where each wafer support structure includes a corresponding cantilever beam structure and a corresponding riser structure, where, for each wafer support structure:
the corresponding cantilever beam structure for that wafer support structure extends radially inward towards the first reference axis from the corresponding riser structure for that wafer support structure,
the corresponding cantilever beam structure for that wafer support structure has a proximal end that is connected with the corresponding riser structure for that wafer support structure, and
the corresponding cantilever beam structure for that wafer support structure has a distal end at which the corresponding wafer support surface for that wafer support structure is located.

Implementation 4: The apparatus of implementation 3, where:
each cantilever beam structure has a corresponding channel in a side of that cantilever beam structure facing away from the first average midplane,
the corresponding channel of each cantilever beam structure is located between the wafer support surface of that cantilever beam structure and the corresponding riser structure connected with the proximal end of that cantilever beam structure, and
the corresponding channel of each cantilever beam structure extends across that cantilever beam structure in a direction that is transverse to a long axis of the cantilever beam structure.

Implementation 5: The apparatus of implementation 4, where each channel is at least 0.75 mm deep.

Implementation 6: The apparatus of any one of implementations 1 through 5, further including a plurality of wafer-centering features, each wafer-centering feature having a corresponding centering surface, where at least a portion of the centering surface of each wafer-centering feature is positioned a third distance from, and faces towards, the first reference axis.

Implementation 7: The apparatus of implementation 6, where the third distance is between 150.5 mm and 150 mm.

Implementation 8: The apparatus of either implementation 6 or implementation 7, where each wafer-centering feature is fixed in space with respect to, and supported by, a corresponding one of the wafer support structures.

Implementation 9: The apparatus of implementation 8, where at least a portion of the centering surface of each wafer-centering feature forms an angle of less than 90 degrees with respect to the first reference axis.

Implementation 10: The apparatus of implementation 8, where at least a portion of the centering surface of each wafer-centering feature forms an acute angle with respect to the first reference axis that is greater than 0 degrees and less than or equal to 30 degrees.

Implementation 11: The apparatus of implementation 6, where the wafer-centering features are wheels.

Implementation 12: The apparatus of implementation 11, where the wheels are made of a ceramic material.

Implementation 13: The apparatus of either implementation 11 or implementation 12, where each wheel is supported by a corresponding one of the wafer support structures relative to the shower-pedestal and is configured to rotate about an axis that is at a fixed distance relative to the first average midplane.

Implementation 14: The apparatus of implementation 13, further including a showerhead having a plurality of second gas distribution ports distributed across a second surface of the showerhead that faces towards the first surface of the shower-pedestal, where:
there are N wheels,
the second surface of the showerhead has N recesses in it, and
each recess is positioned such that a corresponding second reference axis that is perpendicular to the first average midplane and that passes through a center of a corresponding one of the wheels passes through that recess.

Implementation 15: The apparatus of implementation 14, further including a focus ring, where the focus ring:
has a nominally circular inner edge with a diameter that is smaller than twice the third distance and a nominally circular outer edge that has a diameter that is larger than twice the third distance, and
is configured to rest on the wafer support structures, where the focus ring includes N openings proximate the inner edge or N notches along the inner edge that are each positioned such that a portion of a corresponding one of the wheels passes through the opening or notch when the focus ring is supported by the wafer support structures.

Implementation 16: The apparatus of implementation 15, where:
the focus ring has top surface and a bottom surface,
the focus ring is associated with a center axis and a reference plane that is perpendicular to the center axis and coincident with the top surface,
the bottom surface has a first circumferential profile at a radial distance X from the center axis that varies such that a normal distance from the reference plane to the bottom surface at the radial distance X periodically varies between at least a first value and a second value, and
twice X is larger than the diameter of the nominally circular inner edge and smaller than the diameter of the nominally circular outer edge.

Implementation 17: The apparatus of implementation 16, where the focus ring further includes a plurality of protrusions positioned along the bottom surface, each protrusion having a portion lying at the radial distance X from the center axis.

Implementation 18: The apparatus of implementation 17, where each protrusion extends along a corresponding axis that is coplanar with a corresponding reference plane that is coplanar with the center axis.

Implementation 19: The apparatus of implementation 18, where each protrusion is semi-cylindrical in shape.

Implementation 20: The apparatus of implementation 15, where:
the focus ring has an inner portion and an outer portion,
the inner edge is located on the inner portion,
the inner portion is sized such that it cannot pass through an opening defined by an innermost edge of the outer portion, and
the inner portion and the outer portion are not fixedly connected with one another.

Implementation 21: The apparatus of either implementation 11 or implementation 12, further including one or more wheel vertical lift mechanisms, where:
each wheel is supported by a corresponding wheel riser structure,
the one or more vertical lift mechanisms, in aggregate, support the wheel riser structures and are configured to be movable between at least a first configuration and a second configuration,
at least a portion of each wheel is farther from the first average midplane in a direction parallel to the first reference axis than the wafer support surfaces when the one or more vertical lift mechanisms are in the first configuration, and
each wheel is, when the one or more vertical lift mechanisms are in the second configuration, in between the first average midplane and the location that that wheel was in when the one or more vertical lift mechanisms were in the first configuration.

Implementation 22: The apparatus of implementation 21, where:
the one or more vertical lift mechanisms are further configured to be movable between at least the first and second configurations and also a third configuration, and
the first average midplane is in between the wafer support surfaces and at least a portion of each wheel when the one or more vertical lift mechanisms are in the third configuration.

Implementation 23: The apparatus of either implementation 21 or implementation 22, where each wheel riser structure passes through a corresponding notch in an outer edge of the shower-pedestal or through a corresponding hole through the shower-pedestal.

Implementation 24: The apparatus of any one of implementations 21 through 23, where each wheel riser structure is located at a different angular position about the first reference axis than the wafer support structures.

Implementation 25: The apparatus of any one of implementations 21 through 23, where each wheel riser structure is located at the same angular position about the first reference axis as a corresponding one of the wafer support structures.

Implementation 26: The apparatus of implementation 25, where each wafer support structure has an opening therethrough that is sized such that a portion of a corresponding one of the wheel riser structures passes through the opening when the one or more vertical lift mechanisms is moved between the first configuration to the second configuration.

Implementation 27: The apparatus of any one of implementations 1 through 26, further including:
a chamber;
a rotational indexer having a plurality of forks, where:
   the rotational indexer is configured to rotate the plurality of forks about a first rotational axis to at least a first rotational position responsive to one or more inputs,
   each fork has a plurality of wafer lift surfaces,
   a first fork of the plurality of forks is positioned such that the wafer lift surfaces thereof are positioned over the shower-pedestal when the plurality of forks are in the first rotational position.

Implementation 28: The apparatus of implementation 27, where:
the first fork includes two arms that, when the plurality of forks are in the first rotational position, lie entirely outside of a circular region centered on the first reference axis and having a diameter of twice the third distance, and
each of the arms has one or more protrusions that, when the plurality of forks are in the first rotational position, extend inward towards the first reference axis such that a portion of each protrusion having one of the wafer lift surfaces lies within the circular region.

Implementation 29: The apparatus of implementation 28, where each wafer lift surface is non-parallel with respect to the first average midplane.

Implementation 30: The apparatus of implementation 28, where at least a portion of each wafer lift surface forms an angle of greater than zero degrees and equal to or less than 25 degrees with respect to the first average midplane.

Implementation 31: The apparatus of any one of implementations 28 through 30, where:
the forks each include a first half and a second half,
at least one of the wafer lift surfaces of each fork is provided by the first half of that fork,
at least one other of the wafer lift surfaces of each fork is provided by the second half of that fork,
the first halves of the forks are fixed in space with respect to a first hub,
the second halves of the forks are fixed in space with respect to a second hub,
the first hub is connected with a first rotational drive by a first shaft,
the second hub is connected with a second rotational drive by a second shaft, and
the first rotational drive and the second rotational drive are configured to be independently actuated for at least a portion of their rotational range of motion.

Implementation 32: An apparatus for use with semiconductor wafers of diameter D, the apparatus including a ring structure having an inner perimeter defining an opening sized smaller than the semiconductor wafers of diameter D and an outer perimeter sized larger than the semiconductor wafers of diameter D, where:
the ring structure has top surface and a bottom surface,
the ring structure is associated with a center axis and a reference plane that is perpendicular to the center axis and coincident with the top surface,
the bottom surface has a first circumferential profile at a radial distance X from the center axis that varies such that a normal distance from the reference plane to the bottom surface at the radial distance X varies between at least a first value and a second value, and
X is less than 50% of D.

Implementation 33: The apparatus of implementation 32, where the normal distance from the reference plane to the bottom surface at the radial distance X varies periodically.

Implementation 34: The apparatus of implementation 33, where the normal distance from the reference plane to the bottom surface at the radial distance X varies periodically with a periodicity of at least three periods about the circumference of the ring structure.

Implementation 35: The apparatus of implementation 33, where the normal distance from the reference plane to the bottom surface at the radial distance X varies periodically with a periodicity of three periods about the circumference of the ring structure.

Implementation 36: The apparatus of implementation 33, where the normal distance from the reference plane to the bottom surface at the radial distance X varies periodically with a periodicity of four periods about the circumference of the ring structure.

Implementation 37: The apparatus of implementation 33, where the normal distance from the reference plane to the bottom surface at the radial distance X varies periodically with a periodicity of at least four periods and less than or equal to ten periods about the circumference of the ring structure.

Implementation 38: The apparatus of implementation 33, where the normal distance from the reference plane to the bottom surface at the radial distance X varies periodically with a periodicity of more than ten periods and less than or equal to twenty periods about the circumference of the ring structure.

Implementation 39: The apparatus of implementation 33, where the normal distance from the reference plane to the bottom surface at the radial distance X varies periodically with a periodicity of more than twenty periods and less than or equal to thirty periods about the circumference of the ring structure.

Implementation 40: The apparatus of any one of implementations 32 through 39, where:
there are N spaced-apart first locations about the ring structure where the normal distance from the reference plane to the bottom surface at the radial distance X is at the first value,
there are N spaced-apart second locations about the ring structure where the normal distance from the reference plane to the bottom surface at the radial distance X is at the second value,
each first location is circumferentially interposed between two of the second locations,
each second location is circumferentially interposed between two of the first locations, and
N is an integer greater than or equal to three.

Implementation 41: The apparatus of implementation 40, where N is three.

Implementation 42: The apparatus of implementation 40, where N is four.

Implementation 43: The apparatus of implementation 40, where N is an integer greater than three and less than or equal to thirty.

Implementation 44: The apparatus of implementation 40, where N is an integer greater than three and less than or equal to ten.

Implementation 45: The apparatus of implementation 40, where N is an integer greater than ten and less than or equal to twenty.

Implementation 46: The apparatus of implementation 40, where N is an integer greater than twenty and less than or equal to thirty.

Implementation 47: The apparatus of any one of implementations 32 through 46, where the absolute value of the difference between the first value and the second value is greater than zero microns and less than or equal to 400 microns.

Implementation 48: The apparatus of any one of implementations 32 through 46, where the absolute value of the difference between the first value and the second value is greater than zero microns and less than or equal to 100 microns.

Implementation 49: The apparatus of any one of implementations 32 through 46, where the absolute value of the difference between the first value and the second value is greater than or equal to 50 microns and less than or equal to 150 microns.

Implementation 50: The apparatus of any one of implementations 32 through 46, where the absolute value of the difference between the first value and the second value is greater than or equal to 100 microns and less than or equal to 200 microns.

Implementation 51: The apparatus of any one of implementations 32 through 46, where the absolute value of the difference between the first value and the second value is greater than or equal to 150 microns and less than or equal to 250 microns.

Implementation 52: The apparatus of any one of implementations 32 through 46, where the absolute value of the difference between the first value and the second value is greater than or equal to 200 microns and less than or equal to 300 microns.

Implementation 53: The apparatus of any one of implementations 32 through 46, where the absolute value of the difference between the first value and the second value is greater than or equal to 250 microns and less than or equal to 350 microns.

Implementation 54: The apparatus of any one of implementations 32 through 46, where the absolute value of the difference between the first value and the second value is greater than or equal to 300 microns and less than or equal to 400 microns.

Implementation 55: The apparatus of any one of implementations 32 through 46, where the absolute value of the difference between the first value and the second value is greater by a third value than an expected maximum amount of wafer edge sag in the semiconductor wafers when the semiconductor wafers are supported at a plurality of locations along edges thereof.

Implementation 56: The apparatus of implementation 55, where the third value is greater than zero microns and less than or equal to 50 microns.

Implementation 57: The apparatus of implementation 55, where the third value is greater than zero microns and less than or equal to 40 microns.

Implementation 58: The apparatus of implementation 55, where the third value is greater than zero microns and less than or equal to 30 microns.

Implementation 59: The apparatus of implementation 55, where the third value is greater than zero microns and less than or equal to 20 microns.

Implementation 60: The apparatus of any one of implementations 32 through 59, where the top surface is planar.

Implementation 61: The apparatus of any one of implementations 32 through 59, where the top surface is axially symmetric about the center axis.

Implementation 62: The apparatus of any one of implementations 32 through 61, where the top surface has a second circumferential profile that follows the first circumferential profile.

Implementation 63: The apparatus of any one of implementations 32 through 62, where the bottom surface at the radial distance X from the center axis is a wavy conical frustum.

Implementation 64: The apparatus of any one of implementations 32 through 62, where the bottom surface at the radial distance X from the center axis has a radial profile with respect to the center axis that is at an oblique angle with respect to the center axis.

Implementation 65: The apparatus of any one of implementations 32 through 64, where the ring structure is made of a ceramic material.

Implementation 66: The apparatus of implementation 65, where the ceramic material is aluminum oxide.

1. An apparatus comprising:
a shower-pedestal having a plurality of first gas distribution ports distributed across a first surface of the shower-pedestal, the first surface of the shower-pedestal defining a first average midplane; and
a plurality of wafer support structures extending from the shower-pedestal and positioned about a first reference axis that intersects the first surface of the shower-pedestal and is perpendicular to the first average midplane, wherein:
the plurality of wafer support structures are further positioned around a region that includes the first surface of the shower-pedestal,
each wafer support structure has a corresponding wafer support surface that is non-parallel with respect to the first average midplane,
each wafer support surface has a portion that is positioned at least a first distance away from the first average midplane in a direction perpendicular thereto and a second distance from the first reference axis in a direction perpendicular thereto.

2. The apparatus of claim 1, wherein at least a portion of each wafer support surface forms an angle of greater than zero degrees and equal to or less than 15 degrees with respect to the first average midplane.

3. The apparatus of claim 2, wherein each wafer support structure includes a corresponding cantilever beam structure and a corresponding riser structure, wherein, for each wafer support structure:
the corresponding cantilever beam structure for that wafer support structure extends radially inward towards the first reference axis from the corresponding riser structure for that wafer support structure,
the corresponding cantilever beam structure for that wafer support structure has a proximal end that is connected with the corresponding riser structure for that wafer support structure, and
the corresponding cantilever beam structure for that wafer support structure has a distal end at which the corresponding wafer support surface for that wafer support structure is located.

4. The apparatus of claim 3, wherein:
each cantilever beam structure has a corresponding channel in a side of that cantilever beam structure facing away from the first average midplane,
the corresponding channel of each cantilever beam structure is located between the wafer support surface of that cantilever beam structure and the corresponding riser structure connected with the proximal end of that cantilever beam structure, and
the corresponding channel of each cantilever beam structure extends across that cantilever beam structure in a direction that is transverse to a long axis of the cantilever beam structure.

5. The apparatus of claim 4, wherein each channel is at least 0.75 mm deep.

6. The apparatus of claim 1, further comprising a plurality of wafer-centering features, each wafer-centering feature having a corresponding centering surface, wherein at least a portion of the centering surface of each wafer-centering feature is positioned a third distance from, and faces towards, the first reference axis.

7. The apparatus of claim 6, wherein the third distance is between 150.5 mm and 150 mm.

8. The apparatus of claim 6, wherein each wafer-centering feature is fixed in space with respect to, and supported by, a corresponding one of the wafer support structures.

9. The apparatus of claim 8, wherein at least a portion of the centering surface of each wafer-centering feature forms an angle of less than 90 degrees with respect to the first reference axis.

10. The apparatus of claim 8, wherein at least a portion of the centering surface of each wafer-centering feature forms an acute angle with respect to the first reference axis that is greater than 0 degrees and less than or equal to 30 degrees.

11. The apparatus of claim 6, wherein the wafer-centering features are wheels.

12. The apparatus of claim 11, wherein the wheels are made of a ceramic material.

13. The apparatus of claim 11, wherein each wheel is supported by a corresponding one of the wafer support structures relative to the shower-pedestal and is configured to rotate about an axis that is at a fixed distance relative to the first average midplane.

14. The apparatus of claim 13, further comprising a showerhead having a plurality of second gas distribution ports distributed across a second surface of the showerhead that faces towards the first surface of the shower-pedestal, wherein:
there are N wheels,
the second surface of the showerhead has N recesses in it, and
each recess is positioned such that a corresponding second reference axis that is perpendicular to the first average midplane and that passes through a center of a corresponding one of the wheels passes through that recess.

15. The apparatus of claim 14, further comprising a focus ring, wherein the focus ring:
has a nominally circular inner edge with a diameter that is smaller than twice the third distance and a nominally circular outer edge that has a diameter that is larger than twice the third distance, and
is configured to rest on the wafer support structures, wherein the focus ring includes N openings proximate the inner edge or N notches along the inner edge that are each positioned such that a portion of a corresponding one of the wheels passes through the opening or notch when the focus ring is supported by the wafer support structures.

16. The apparatus of claim 15, wherein:
the focus ring has top surface and a bottom surface,
the focus ring is associated with a center axis and a reference plane that is perpendicular to the center axis and coincident with the top surface,
the bottom surface has a first circumferential profile at a radial distance X from the center axis that varies such that a normal distance from the reference plane to the bottom surface at the radial distance X periodically varies between at least a first value and a second value, and
twice X is larger than the diameter of the nominally circular inner edge and smaller than the diameter of the nominally circular outer edge.

17. The apparatus of claim 16, wherein the focus ring further includes a plurality of protrusions positioned along the bottom surface, each protrusion having a portion lying at the radial distance X from the center axis.

18. The apparatus of claim 17, wherein each protrusion extends along a corresponding axis that is coplanar with a corresponding reference plane that is coplanar with the center axis.

19. The apparatus of claim 18, wherein each protrusion is semi-cylindrical in shape.

20. The apparatus of claim 15, wherein:
the focus ring has an inner portion and an outer portion,
the inner edge is located on the inner portion,
the inner portion is sized such that it cannot pass through an opening defined by an innermost edge of the outer portion, and
the inner portion and the outer portion are not fixedly connected with one another.

21. The apparatus of claim 11, further comprising one or more vertical lift mechanisms, wherein:
each wheel is supported by a corresponding wheel riser structure,
the one or more vertical lift mechanisms, in aggregate, support the wheel riser structures and are configured to be movable between at least a first configuration and a second configuration,
at least a portion of each wheel is farther from the first average midplane in a direction parallel to the first reference axis than the wafer support surfaces when the one or more vertical lift mechanisms are in the first configuration, and
each wheel is, when the one or more vertical lift mechanisms are in the second configuration, in between the first average midplane and a location that that wheel was in when the one or more vertical lift mechanisms were in the first configuration.

22. The apparatus of claim 21, wherein:
the one or more vertical lift mechanisms are further configured to be movable between at least the first and second configurations and also a third configuration, and
the first average midplane is in between the wafer support surfaces and at least a portion of each wheel when the one or more vertical lift mechanisms are in the third configuration.

23. The apparatus of claim 21, wherein each wheel riser structure passes through a corresponding notch in an outer edge of the shower-pedestal or through a corresponding hole through the shower-pedestal.

24. The apparatus of claim 21, wherein each wheel riser structure is located at a different angular position about the first reference axis than the wafer support structures.

25. The apparatus of claim 21, wherein each wheel riser structure is located at the same angular position about the first reference axis as a corresponding one of the wafer support structures.

26. The apparatus of claim 25, wherein each wafer support structure has an opening therethrough that is sized such that a portion of a corresponding one of the wheel riser structures passes through the opening when the one or more vertical lift mechanisms is moved between the first configuration to the second configuration.

27. The apparatus of claim 1, further comprising:
a chamber; and
a rotational indexer having a plurality of forks, wherein:
the rotational indexer is configured to rotate the plurality of forks about a first rotational axis to at least a first rotational position responsive to one or more inputs,
each fork has a plurality of wafer lift surfaces,
a first fork of the plurality of forks is positioned such that the wafer lift surfaces thereof are positioned over the shower-pedestal when the plurality of forks are in the first rotational position.

28. The apparatus of claim 27, wherein:
the first fork includes two arms that, when the plurality of forks are in the first rotational position, lie entirely outside of a circular region centered on the first reference axis and having a diameter of twice the third distance, and
each of the arms has one or more protrusions that, when the plurality of forks are in the first rotational position, extend inward towards the first reference axis such that a portion of each protrusion having one of the wafer lift surfaces lies within the circular region.

29. The apparatus of claim 28, wherein each wafer lift surface is non-parallel with respect to the first average midplane.

30. The apparatus of claim 28, wherein at least a portion of each wafer lift surface forms an angle of greater than zero degrees and equal to or less than 25 degrees with respect to the first average midplane.

31. The apparatus of claim 28, wherein:
the forks each include a first half and a second half,
at least one of the wafer lift surfaces of each fork is provided by the first half of that fork,
at least one other of the wafer lift surfaces of each fork is provided by the second half of that fork,
the first halves of the forks are fixed in space with respect to a first hub,
the second halves of the forks are fixed in space with respect to a second hub,
the first hub is connected with a first rotational drive by a first shaft,
the second hub is connected with a second rotational drive by a second shaft, and
the first rotational drive and the second rotational drive are configured to be independently actuated for at least a portion of their rotational range of motion.
